(19) United States
(12) Patent Application Publication
(10) Pub. No.: US 2007/0092646 A1
(43) Pub. Date: Apr. 26, 2007

(54) SUBSTRATE PROCESSING APPARATUS AND SUBSTRATE PROCESSING METHOD

(75) Inventors: Hiroyuki SHINOZAKI, Minato-ku (JP); Yasushi KOJIMA, Minato-ku (JP); Shunichi AIYOSHIZAWA, Fujisawa-shi (JP); Kiwamu TSUKAMOTO, Fujisawa-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: e-Beam Corporation, Minato-ku (JP)

(21) Appl. No.: 11/614,310

(22) Filed: Dec. 21, 2006

Related U.S. Application Data
(62) Division of application No. 11/322,270, filed on Jan. 3, 2006.

(30) Foreign Application Priority Data
Jan. 28, 2005 (JP) 2005-021098
Mar. 10, 2005 (JP) 2005-067572

(51) Int. Cl. C23C 16/00

(52) U.S. Cl. 427/248.1; 118/715

(57) ABSTRACT

A substrate treatment apparatus that treats a substrate under treatment has an interface section, a substrate loading/unloading section, a reduced pressure atmosphere conveyance chamber, and an exposure treatment chamber. The interface section has a conveyance mechanism that can freely load and unload the substrate under treatment from another device into the apparatus or vice versa. The substrate under treatment can be loaded and unloaded into and from the substrate loading/unloading section in one direction by the conveyance mechanism of the interface section. The reduced pressure atmosphere conveyance chamber is disposed adjacent to and perpendicular to the direction of the substrate loading/unloading section and has a conveyance mechanism that conveys the substrate under treatment under a reduced pressure atmosphere. The exposure treatment chamber is disposed adjacent to and in parallel with the direction of the reduced pressure atmosphere conveyance chamber and performs an exposure treatment for the substrate under treatment.

### Background of the Invention

1. Field of the Invention

The present invention relates to a substrate treatment apparatus and a substrate treatment method.

2. Description of the Related Art

An apparatus that has a loader, a conveyance device thereof, a load lock chamber, a conveyance chamber, a conveyance device thereof, and a reduced pressure atmosphere treatment chamber is known. In this apparatus, the conveyance device of the loader that conveys a semiconductor wafer under a normal atmosphere. The conveyance device conveys the semiconductor wafer to the load lock chamber that changes the inner atmosphere from the normal atmosphere to a reduced pressure atmosphere. The conveyance device of the conveyance chamber transfers the semiconductor wafer from the load lock chamber to the reduced pressure atmosphere treatment chamber. This apparatus is disclosed for example in Patent Document 1. In addition, an apparatus that inline-connects a resist treatment device that applies resist onto a semiconductor wafer and an exposure treatment device that performs an exposure treatment for the semiconductor wafer that has been coated with a resist file. This apparatus is disclosed for example in Patent Document 2.

[Patent Document 1] Japanese Patent Application Laid-Open Publication No. HEI 7-321178 (see FIG. 1).

[Patent Document 2] Japanese Patent Application Laid-Open Publication No. 2001-77014 (see FIG. 1, paragraph 47).

### SUMMARY OF THE INVENTION

However, in the foregoing apparatus (Patent Document 1), the loader, the load lock chamber, the conveyance chamber, and the treatment chamber are connected in series. Thus, the footprints of these sections need to be added in the direction of which they are connected. As a result, the areas of the footprints of the whole apparatus increase. Thus, as a problem of this apparatus, the size of the apparatus cannot be decreased. In addition, since the conveyance chamber is disposed around other treatment chambers, it is difficult to perform maintenance work for the conveyance chamber. Thus, the work efficiency of the maintenance work lowers and the hour cost for the maintenance work increases. In addition, although a standalone system is known, concepts of a system that controls another device that is inline-connected and a system that considers the arrangement of devices are not known. Thus, the efficiency of a treatment process for a semiconductor wafer in the whole system cannot be improved.

Although the foregoing second apparatus (Patent Document 2) is an apparatus that inline-connects the resist treatment device and the exposure treatment device that performs an exposure treatment for the semiconductor wafer that has been coated with a resist file, the apparatus lacks for a concept of which the exposure treatment device performs the treatment under a reduced pressure atmosphere. When a semiconductor wafer is transferred to an in-stage and an out-stage of the exposure treatment device, the semiconductor wafer is not aligned. Thus, the semiconductor wafer cannot be accurately aligned at an alignment step. As a result, the alignment time for a semiconductor wafer in the exposure treatment device increases and the throughput lowers.

Moreover, in the resist treatment device and the exposure treatment device, atmospheric environment is not considered. Therefore, cross-contamination takes place between the resist treatment device and the exposure treatment device. Thus, the yield of semiconductor wafers cannot be specified. As a result, the yield cannot be improved.

The control mechanism of the resist treatment device receives an exposure end signal from the exposure treatment device and the resist treatment device controls the exposure treatment device so that a time period after the end of the exposure treatment until a semiconductor wafer is conveyed to the heat treatment device becomes constant. However, the mechanism manages only the exposure end time, not consider a change of a resist film under a reduced pressure atmosphere such as a time period in the exposure treatment device under the reduced pressure atmosphere. Since it is difficult for the control mechanism of the resist treatment device to manage such an atmosphere, the yield of semiconductor wafers cannot be improved.

In addition, the conveyance mechanism of the resist treatment device cannot convey a semiconductor wafer from the exposure treatment device to the heat treatment device unless the semiconductor wafer has been conveyed through a plurality of conveyance devices. The plurality of conveyance devices spend a lot of time. Thus, a conveyance time period for which a semiconductor wafer is conveyed from the exposure treatment device to the heat treatment device cannot be kept constant. As a result, the yield of semiconductor wafers cannot be improved.

When a conveyance time period after the end of exposure treatment until a semiconductor wafer is conveyed to the heat treatment device is constant, each conveyance device needs to hold a semiconductor wafer corresponding to the constant conveyance time period. Until the conveyance time period has elapsed, each conveyance device cannot convey a semiconductor wafer. Thus, the throughput of the conveyance process lowers.

The present invention is made from the foregoing point of view. An object of the present invention is to provide a substrate treatment apparatus and a substrate treatment method that allow the throughput of a treatment for substrates to be improved and the yield of substrates under treatment to be improved.

(1) To solve the problems of the related art, one aspect of the present invention is a substrate treatment apparatus that treats a substrate under treatment, the apparatus having a substrate loading/unloading section into and from which a substrate under treatment can be loaded from and into the outside of the apparatus in one direction; a reduced pressure atmosphere conveyance chamber that is disposed adjacent to and perpendicular to the direction of the substrate loading/unloading section and that has a conveyance mechanism that conveys the substrate under treatment under a reduced pressure atmosphere; and an exposure treatment chamber that is disposed adjacent to and in parallel with the direction of the reduced pressure atmosphere conveyance chamber and that performs an exposure treatment for the substrate under treatment.

Another aspect of the present invention is a substrate treatment apparatus that treats a substrate under treatment, the substrate treatment apparatus having an interface section that has a conveyance mechanism that can freely load and unload a substrate under treatment into and from another device; a vacuum atmosphere preparation chamber into and from which the substrate under treatment can be freely loaded by the conveyance mechanism of the interface section in the direction; a reduced pressure atmosphere conveyance chamber that is disposed adjacent to and nearly perpendicular to the direction of the vacuum atmosphere preparation chamber and that has a conveyance mechanism that conveys the substrate under treatment under a reduced pressure atmosphere; and an exposure treatment chamber that is disposed adjacent to and in parallel with the direction of the reduced pressure atmosphere conveyance chamber and that performs an exposure treatment for the substrate under treatment.

Another aspect of the present invention is a substrate treatment apparatus that treats substrate under treatment, the substrate treatment apparatus having an interface section that has a conveyance mechanism that can freely load and unload a substrate under treatment into and from another device; an alignment mechanism that is disposed in the interface section and that aligns the substrate under treatment; a vacuum atmosphere preparation chamber into and from which the substrate under treatment aligned by the alignment mechanism can be freely loaded and unloaded by the conveyance mechanism in the direction; a reduced pressure atmosphere conveyance chamber that is disposed adjacent to and nearly perpendicular to the direction of the vacuum atmosphere preparation chamber and that has a conveyance mechanism that conveys the substrate under treatment under a reduced pressure atmosphere; an exposure treatment chamber that is disposed adjacent to and in parallel with the direction of the reduced pressure atmosphere conveyance chamber and that performs an exposure treatment for the substrate under treatment; a heat treatment section that is disposed in the interface section and that performs a heat treatment for the substrate under treatment for which the exposure treatment has been performed in the exposure treatment chamber; and at least one control mechanism that controls the treatment of the heat treatment section and the conveyance of the conveyance mechanism.

Another aspect of the present invention is a substrate treatment apparatus that treats a substrate under treatment, the apparatus having a substrate loading/unloading section into and from which the substrate under treatment can be freely loaded in one direction; a detection mechanism that is disposed in the substrate loading/unloading section and that detects that the substrate under treatment has been aligned; a reduced pressure atmosphere conveyance chamber that is disposed adjacent to and nearly perpendicular to the direction of the substrate loading/unloading section and that has a conveyance mechanism that conveys the substrate under treatment under a reduced pressure atmosphere; an exposure treatment chamber that is disposed adjacent to and in parallel with the direction of the reduced pressure atmosphere conveyance chamber and that performs an exposure treatment for the substrate under treatment; and a stage that is disposed in the exposure treatment chamber and that can be freely moved to a load position of the substrate under treatment conveyed from the conveyance mechanism according to detection data of the detection mechanism.

Another aspect of the present invention is a substrate treatment apparatus that treats a substrate under treatment, the apparatus having a substrate loading/unloading section into and from which the substrate under treatment that has been aligned by another device with a predetermined accuracy can be loaded and unloaded in one direction; a reduced pressure atmosphere conveyance chamber that is disposed adjacent to and nearly perpendicular to the direction of the substrate loading/unloading section and that has a conveyance mechanism that conveys the substrate under treatment under a reduced pressure atmosphere; an exposure treatment chamber that is disposed adjacent to and in parallel with the direction of the reduced pressure atmosphere conveyance chamber and that performs an exposure treatment for the substrate under treatment; and an alignment mechanism that is disposed in the substrate loading/unloading section or/and the reduced pressure atmosphere conveyance chamber and that aligns the substrate under treatment with a higher accuracy than the predetermined accuracy.

Another aspect of the present invention is a substrate treatment apparatus that treats a substrate under treatment, the apparatus having an interface section that has a conveyance mechanism can freely load and unload the substrate under treatment; a vacuum atmosphere preparation chamber into and from which the substrate under treatment can be freely loaded and unloaded by the conveyance mechanism of the interface section in one direction; a reduced pressure atmosphere conveyance chamber that is disposed adjacent to and nearly perpendicular to the direction of the vacuum atmosphere preparation chamber and that has a conveyance mechanism that conveys the substrate under treatment under a reduced pressure atmosphere; an exposure treatment chamber that is disposed adjacent to and in parallel with the direction of the reduced pressure atmosphere conveyance chamber and that performs an exposure treatment for the substrate under treatment; and alignment mechanisms that are disposed at two or more sections of the interface section, the vacuum atmosphere preparation chamber, the reduced pressure atmosphere conveyance chamber, and the exposure treatment chamber and that align the substrate under treatment.

Another aspect of the present invention is a substrate treatment apparatus that treats a substrate under treatment, the apparatus having an interface section that has a conveyance mechanism that can freely load and unload the substrate under treatment; a vacuum atmosphere preparation chamber into and from which the substrate under treatment can be freely loaded and unloaded by the conveyance mechanism of the interface section in one direction; a reduced pressure atmosphere conveyance chamber that is disposed adjacent to and nearly perpendicular to the direction of the vacuum atmosphere preparation chamber and that has a conveyance mechanism that conveys the substrate under treatment under a reduced pressure atmosphere; an exposure treatment chamber that is disposed adjacent to and in parallel with the direction of the reduced pressure atmosphere conveyance chamber and that performs an exposure treatment for the substrate under treatment; a first alignment mechanism that is disposed in the interface section and that aligns the substrate under treatment with a first accuracy; and a second alignment mechanism that is disposed in the reduced pressure atmosphere conveyance chamber or/and the exposure treatment chamber with a second accuracy higher than the first accuracy.

Another aspect of the present invention is a substrate treatment apparatus that treats a substrate under treatment, the apparatus having an interface section that has a conveyance mechanism that can freely load and unload the substrate under treatment into and from another device; a vacuum atmosphere preparation chamber into and from which the substrate under treatment can be freely loaded and unloaded by the conveyance mechanism of the interface section in one direction and that is disposed in the interface section adjacent to a work space for the other device; a reduced pressure atmosphere conveyance chamber that is disposed adjacent to and nearly perpendicular to the direction of the vacuum atmosphere preparation chamber and that has a conveyance mechanism that conveys the substrate under treatment under a reduced pressure atmosphere; an exposure treatment chamber that is disposed adjacent to and in parallel with the direction of the reduced pressure atmosphere conveyance chamber and that performs an exposure treatment for the substrate under treatment; an alignment mechanisms that is disposed in the interface section adjacent to the vacuum atmosphere preparation chamber and that aligns the substrate under treatment with a first accuracy; and a heat treatment mechanism that is disposed in the interface section opposite to the alignment mechanism of the conveyance mechanism and that performs a heat treatment for the substrate under treatment.

Another aspect of the present invention is a an apparatus having a device that applies resist solution onto a substrate under treatment; a conveyance mechanism that can freely convey the substrate under treatment to a device that performs an exposure treatment for the substrate under treatment that has been coated with a resist film; a heat treatment section that performs a predetermined heat treatment for the substrate under treatment that has been received from the device that performs the exposure treatment; and an alignment mechanism that aligns the substrate under treatment that has been received from the device that applies the resist solution onto the substrate under treatment.

Another aspect of the present invention is an apparatus that has a linear space portion; an alignment mechanism that is disposed at one end of the space portion and that aligns a substrate under treatment received from a device that applies resist solution onto the substrate under treatment; a heat treatment section that is disposed at the other end of the space portion and that performs a predetermined heat treatment for the substrate under treatment received from a device that performs an exposure treatment; and a conveyance mechanism that is disposed between the heat treatment section and the alignment mechanism and that can freely convey the substrate under treatment.

Another aspect of the present invention is a substrate treatment method. A substrate under treatment is aligned with a first accuracy under a normal atmosphere or a positive pressure atmosphere with a first accuracy. The substrate under treatment is aligned with a second accuracy higher than the first accuracy under a reduced pressure atmosphere. Thereafter, a predetermined treatment is preformed for the substrate under treatment.

Another aspect of the present invention is a substrate treatment method. A substrate under treatment is aligned by a first control mechanism with a first accuracy under a normal atmosphere or under a positive atmosphere. The substrate under treatment is aligned by a second control mechanism that controls the first control mechanism with a second accuracy higher than the first accuracy under a reduced pressure atmosphere. Thereafter, a predetermined treatment is performed for the substrate under treatment.

Another aspect of the present invention is a substrate treatment method. A substrate under treatment is conveyed from another device by a conveyance mechanism controlled by a first control mechanism. An exposure treatment is performed for the substrate under treatment by a second control mechanism that manages the first control mechanism. The substrate under treatment for which the exposure treatment has been performed is conveyed to a heat treatment device by a conveyance mechanism controlled by the first control mechanism. The substrate under treatment is conveyed to another device by a conveyance mechanism controlled by the first control mechanism.

Another aspect of the present invention is a substrate treatment method. A substrate under treatment received from a device that applies resist solution onto the substrate under treatment is aligned. A heat treatment is performed for a substrate under treatment received from a device that performs an exposure treatment for the substrate under treatment at a predetermined temperature according to information received from the device that performs the exposure treatment.

Another aspect of the present invention is a substrate treatment method. A substrate under treatment received from a device that applies resist solution onto the substrate under treatment is aligned. A heat treatment is performed for a substrate under treatment received from a device that performs an exposure treatment at a predetermined temperature according to information received from the device that performs the exposure treatment. Temperature information of the heat treatment or/and information about the end time of the heat treatment are transmitted to the device that applies the resist solution onto the substrate under treatment.

(2) A conventional electron beam lithography device uses the following method so that the angular misalignments between moving coordinates Xs and Ys of an XY stage and pattern forming coordinates Xw and Yw on a substrate satisfy allowable values.

1) A θ axis stage with which the rotation of a substrate is aligned is disposed on the XY stage.

2) A stop portion that fits an edge of a substrate and aligns the rotation of the substrate is disposed on the XY stage.

3) Before a substrate is loaded into an electron beam lithography chamber, the coordinate angle of the substrate is aligned in a chamber that has the θ stage with which the rotation of the substrate is aligned. Thereafter, the substrate is loaded into the electron beam lithography chamber.

In the methods 1) and 2), the rotation position of a wafer needs to be detected. Thus, as disclosed in for example Patent Document 3, a method of detecting the wafer position according to a wafer image captured by a camera is known. These technologies need three or more cameras to obtain necessary wafer image information.

[Patent Document 3] Japanese Patent Application Laid-Open Publication No. HEI 9-186061

In a conventional electron beam lithography device that has an XY stage disposed in a wafer chamber, misalignments in the X and Y directions of a wafer conveyed onto the XY stage are permissible as long as the wafer can be normally conveyed. This is because after the wafer is placed on the XY stage, a position mark on the wafer is detected. The amounts of misalignments in the X and Y directions of the wafer are detected. With the detected amounts, the alignment target position of the XY stage is corrected. As a result, the wafer can be aligned with a desired lithography accuracy.

However, a wafer rotation position detection device disposed in the wafer rotation alignment device detects the center of the wafer and the notch position. With the center position and notch position of a reference wafer, the deviations in the X and Y directions of the wafer are obtained. With the deviations and the distance between the center and the notch position of the wafer, the rotation position of the wafer is calculated. Thus, three or more cameras are required to obtain position information of a wafer with wafer images.

When the rotation of a wafer is aligned, the positions X and Y on the horizontal plane of the wafer need to be obtained with contour information of the wafer. Thus, the size and cost of the detection device will increase.

When the position of a wafer under a vacuum atmosphere is detected, it is necessary to provide a vacuum atmospheric camera or a transparent observation window so that a wafer image can be obtained from the air atmosphere side. Thus, the vacuum atmospheric chamber will become large and the number of structural parts will increase. In addition, as the number of seal portions increase, the leak amount will increase.

The present invention is also made from the foregoing point of view. Another object of the present invention is to provide a wafer rotation position detection apparatus, a detection method thereof, and a single wafer treatment apparatus that allow the rotation position of a wafer to be detected with one camera.

An aspect of the present invention is a wafer rotation position detection apparatus that has a stage on which a wafer is placed; one photographing device that photographs a contour image of the wafer, the contour image containing a notch portion of the wafer placed on the stage; a first visual field setting section that sets a fixed first visual field having a vertical reference line and a horizontal reference line in a visual field of the photographing device; a second visual field setting section that sets a movable second visual field having two edge position detection lines in the first visual field, the second visual field being narrower than the first visual field, the two edge position detection lines being in parallel with the vertical reference line with which an outer edge position of the wafer is detected; a notch representative position detection section that detects a representative notch position from the wafer contour image photographed by the photographing device and obtains the misalignment amount between a preset reference notch position and the detected notch representative position; a second visual field moving section that moves the second visual field in the first visual field according to the obtained misalignment amount; an edge position detection section that detects an edge position that is an intersection of the outer periphery of the wafer and the edge position detection lines with the edge position detection lines in the second visual field moved by the second visual field moving section; and a wafer rotation amount calculation section that obtains the distance between the detected edge position and the horizontal reference line and calculates the amount of the rotation of the wafer according to the distance.

Another aspect of the present invention is a wafer rotation position detection apparatus that has a stage on which a wafer is placed; one photographing device that photographs a contour image of the wafer, the contour image containing a notch portion of the wafer placed on the stage; a first detection frame setting section that sets a movable first detection frame in a visual field of the photographing device, the first detection frame having a horizontal reference line and a preset reference position being used to recognize the notch shape of the wafer by pattern matching; a first detection frame moving section that moves the first detection frame to perform the pattern matching; a second detection frame setting section that sets a second detection frame in the visual field of the photographing device to detect an edge of the wafer, the second detection frame moving as the first detection frame moves so that the second detection frame has a predetermined distance to one of the coordinates of the reference position; an edge position detection section that detects an edge position that is an intersection of the second detection frame and the outer periphery of the wafer when the pattern matching has been performed; and a wafer rotation amount calculation section that obtains the distance between the detected edge position and the horizontal reference line and calculates the amount of the rotation of the wafer according to the obtained distance.

Another aspect of the present invention is a wafer rotation position detection apparatus that has a stage on which a wafer is placed; one photographing device that photographs a contour image of the wafer, the contour image containing a notch portion of the wafer placed on the stage; a first detection frame setting section that sets a movable first detection frame in a visual field of the photographing device, the first detection frame having a horizontal reference line and a preset reference position being used to recognize the notch shape of the wafer by pattern matching; a first detection frame moving section that moves the first detection frame to perform the pattern matching; a second detection frame setting section that sets a second detection frame in the visual field of the photographing device to detect an edge of the wafer, the second detection frame moving as the first detection frame moves; a third detection frame setting section that sets a plurality of third detection frames in the visual field of the photographing device, the third detection frame setting sections moving as the first detection frame moves so that the plurality of third detection frames have a predetermined distance to one of the coordinates of the reference position; a notch representative position detection section that detects a notch representative position that is the center of a virtual circle in contact with the notch portion of the wafer according to the coordinates of intersections of the plurality of third detection frames and the outer periphery of the wafer when the pattern matching has been performed; an edge position detection section that detects an edge position that is an intersection of the second detection frame and the outer periphery of the wafer when the pattern matching has been performed; and a wafer rotation amount calculation section that obtains the distance between the detected edge position and the horizontal reference line and calculates the amount of the rotation of the wafer according to the obtained distance.

Another aspect of the present invention is a single wafer treatment apparatus that has one of the foregoing wafer rotation position detection apparatuses; a wafer treatment chamber that has an XY stage on which the wafer is place and that treats the wafer placed on the XY stage; a robot that rotates and conveys the wafer whose rotation position has been detected by the wafer rotation position detection device onto the XY stage of the wafer treatment chamber; a rotation amount calculation section that calculates the rotation amount and the moving amount of the robot according to the wafer rotation position detected by the wafer rotation position detection device; a robot control section that controls the rotation of the robot according to the calculated rotation amount and moving amount; an XY stage moving amount calculation section that calculates the moving amount of the XY stage so that the misalignment amount between the center position of the wafer conveyed to the wafer treatment chamber and the center position of a reference wafer on the XY stage becomes a allowable value or less; and an XY stage driving section that drives the XY stage according to the calculated moving amount of the XY stage.

The wafer rotation position detection apparatus may be disposed in a first chamber. The robot may be disposed in a second chamber connected to the first chamber through a first gate valve and connected to the wafer treatment chamber through a second gate valve.

In the first chamber, the second chamber, and the wafer treatment chamber, the vacuum degree of the first chamber may be the highest, the vacuum degree of the second chamber may be the next highest, and the vacuum degree of the wafer treatment chamber may be the lowest.

The wafer treatment chamber may have an exposure device that emits an electron beam onto resist formed on the wafer.

Another aspect of the present invention is a wafer rotation position detection method. A contour image of a wafer placed on a stage is photographed by one photographing device, the contour image containing a notch portion of the wafer. A fixed first visual field having a vertical reference line and a horizontal reference line is set in a visual field of the photographing device. A movable second visual field having two edge position detection lines is set in the first visual field, the second visual field being narrower than the first visual field, the two edge position detection lines being in parallel with the vertical reference line with which an outer edge position of the wafer is detected. A representative notch position is detected from the wafer contour image photographed by the photographing device. The misalignment amount between a preset reference notch position and the detected notch representative position is obtained. The second visual field in the first visual field is moved according to the obtained misalignment amount. An edge position that is an intersection of the outer periphery of the wafer and the edge position detection lines are detected with the edge position detection lines in the moved second visual field moved. The distance between the detected edge position and the horizontal reference line is obtained. The amount of the rotation of the wafer is calculated according to the obtained distance.

According to the present invention, the rotation position of a wafer can be detected by one camera.

(3) When a semiconductor device is manufactured, at a particular manufacturing step, a wafer needs to be placed at a correct position on a stage and then a treatment for the wafer needs to be performed (for example, an exposure treatment that emits an electron beam onto a resist layer formed on the wafer). To do that, the wafer needs to be aligned at a correct position by rotating and moving the wafer from the current position on the stage.

A method of aligning a wafer at a correct position on a stage with current position information of the wafer that has a notch groove on the stage is known (for example, see Patent Document 4). In this technology of the related art disclosed as Patent Document 4, a virtual position (reference position) corresponding to a contact position of a pre-alignment type reference pin to a wafer is set in an observation visual field. The misalignment mount of the wafer in the observation visual field from the virtual position of the edge position is obtained. With the obtained misalignment amount, offsets in the X direction and the Y direction of the wafer and the rotation error are obtained. In the technology of the related art disclosed in Patent Document 4, the center point of the pin as the reference position of the notch groove is obtained assuming that the boundary of the edge of the notch groove is straight.

[Patent Document 4] Japanese Patent Application Laid-Open Publication No. HEI 9-186061.

Detailed information about dimensional tolerance of the notch groove of a wafer is defined in the SEMI standard. Since the edge portion of a notch groove may not be straight in each wafer manufactured by some manufacturers. Thus, the accuracies of the offsets and rotation error of a wafer calculated according to the technology of the related art disclosed in Patent Document 4 may be low or the offsets and rotation error may not be measured.

When the difference of notch shapes of wafers in a single wafer treatment is large, if the technology of the related art disclosed in Patent Document 4 is used, it is necessary to change fixed values used to calculate the offsets and rotation error for each wafer that differs in notch shape. Thus, the treatment time for the single wafer treatment will increase.

The present invention is also made from the foregoing point of view. Another object of the present invention is to provide a wafer alignment method, a wafer alignment apparatus, and an exposure apparatus that uses the wafer alignment apparatus that allow the alignment accuracy for a wafer to be improved and the treatment time for wafers that have large differences in notch shapes not to increase.

An aspect of the present invention is a wafer alignment apparatus that has at least three detectors that obtain image information of a wafer placed on a stage, the wafer having a notch groove; a calculation section that calculates the center of the wafer and a reference point of the notch groove according to the image information obtained by the detectors; a section that calculates a rotational angle of the wafer according to a calculated result of the calculation section; and a section that drives the rotation of the wafer around an axis perpendicular to a horizontal plane of the stage by the calculated rotation angle.

The detectors preferably have a CCD camera or an optical microscope.

The reference point of the notch groove is preferably the center of the circle when the curved shape of the bottom of the notch groove is circular.

The stage may have a coordinate system composed of a first coordinate axis in the direction of which the wafer is loaded and unloaded and a second coordinate axis that is placed on the horizontal plane of the stage and that is perpendicular to the first coordinate axis. The rotation angle of the wafer may be an angle made by a straight line that connects the calculated center of the wafer and the reference point of the notch groove and the first coordinate axis.

It is preferred that the apparatus further have a horizontal alignment section that horizontally aligns the wafer according to the coordinates of the center of the wafer.

Another aspect of the present invention is an exposure apparatus that has a first chamber that has the foregoing wafer alignment apparatus; a second chamber that is connected to the first chamber through a first gate value and that has a robot that conveys the wafer aligned in the first chamber; and an exposure chamber that is connected to the second camber through a second gate value and that emits an electron beam onto resist formed on the wafer.

Another aspect of the present invention is a wafer alignment method. At least three pieces of image information of a wafer placed on a stage are obtained, the wafer having a notch groove. The center of the wafer and a reference point of the notch groove are calculated according to the obtained image information. A rotational angle of the wafer is calculated according to the calculated result. The rotation of the wafer is driven around an axis perpendicular to a horizontal plane of the stage by the calculated rotation angle.

The reference point of the notch groove is preferably the center of the circle when the curved shape of the bottom of the notch groove is circular.

The stage may have a coordinate system composed of a first coordinate axis in the direction of which the wafer is loaded and unloaded and a second coordinate axis that is placed on the horizontal plane of the stage and that is perpendicular to the first coordinate axis. The rotation angle of the wafer may be an angle made by a straight line that connects the calculated center of the wafer and the reference point of the notch groove and the first coordinate axis.

Thus, according to the present invention, the size of the apparatus can be reduced. In addition, the throughput of the treatment of a substrate under treatment can be improved and the yield of the substrate under treatment can be improved. According to the present invention, the rotation position of the wafer can be detected with one camera. According to the present invention, the alignment accuracy of the wafer can be improved. In addition, the treatment time for wafers whose notch shapes largely differ can be prevented from increasing.

These and other objects, features and advantages of the present invention will become more apparent in light of the following detailed description of a best mode embodiment thereof, as illustrated in the accompanying drawings.

### BRIEF DESCRIPTION OF DRAWINGS

FIG. 1 is an outlined plan view showing the structure of a substrate treatment apparatus according to an embodiment of the present invention;

FIG. 2 is an outlined perspective view describing the structure of an air aligner shown in FIG. 1;

FIG. 3 is an outlined perspective view describing the structure of a heat treatment section shown in FIG. 2;

FIG. 4 is an outlined sectional view describing the structure of the heat treatment section shown in FIG. 2;

FIG. 5 is an outlined sectional view describing the air aligner shown in FIG. 2;

FIG. 6 is an outlined plan view describing the structure of a vacuum atmosphere preparation chamber shown in FIG. 1;

FIG. 7 is an outlined sectional view describing the structure of a reduced pressure atmosphere conveyance chamber shown in FIG. 1;

FIG. 8 is an outlined plan view describing an exposure treatment section shown in FIG. 1;

FIG. 9 is a flow chart describing treatments of the substrate treatment apparatus shown in FIG. 1;

FIG. 10 is an outlined sectional view describing the structure of the exposure treatment chamber shown in FIG. 1;

FIG. 11 is an outlined sectional view describing the structure of principle sections of the exposure treatment chamber shown in FIG. 10;

FIG. 12 is an outlined sectional view describing the structure of the principle sections of the exposure treatment chamber shown in FIG. 10;

FIG. 13 is an outlined plan view describing the structure of the principle sections of a stage shown in FIG. 12;

FIG. 14 is an outlined plan view describing the structure of the exposure treatment section shown in FIG. 1;

FIG. 15 is an outlined sectional view describing the structure of the exposure treatment section shown in FIG. 1;

FIG. 16 is an outlined sectional view describing the structure of the substrate treatment apparatus shown in FIG. 1;

FIG. 17 is an outlined perspective view describing the structure of the exposure treatment section shown in FIG. 1;

FIG. 18 is an outlined plan view describing the structure of the substrate treatment apparatus shown in FIG. 1;

FIG. 19 is an outlined block diagram describing the structure of a control system of the substrate treatment apparatus shown in FIG. 1;

FIG. 20 is an outlined plan view showing the structure of a substrate treatment apparatus according to another embodiment of the present invention;

FIG. 21 is an outlined perspective view describing the structure of a substrate loading/unloading section shown in FIG. 20;

FIG. 22 is an outlined plan view showing the structure of a substrate treatment apparatus according to another embodiment of the present invention;

FIG. 23 is an outlined side view showing the structure of an air flow path according to another embodiment of the present invention;

FIG. 24 is an outlined plan view showing the structure of the substrate treatment apparatus shown in FIG. 23;

FIG. 25 is an outlined perspective view showing the structure of the substrate treatment apparatus according to another embodiment of the present invention;

FIG. 26 is an outlined plan view showing the structure of the substrate treatment apparatus according to the other embodiment of the present invention;

FIG. 27 is an outlined schematic diagram showing the structure of the principle sections of the substrate treatment apparatus shown in FIG. 26;

FIG. 28A and FIG. 28B are schematic diagrams showing the structure of a wafer rotation position detection apparatus according to a second embodiment of the present invention;

FIG. 29 is a schematic diagram describing the operation of the wafer rotation position detection apparatus according to the second embodiment;

FIG. 30 is a schematic diagram describing the operation of the wafer rotation position detection apparatus according to the second embodiment;

FIG. 31 is a schematic diagram describing the operation of the wafer rotation position detection apparatus according to the second embodiment;

FIG. 32 is a block diagram showing the structure of an image process device of a wafer rotation position detection apparatus according to a third embodiment of the present invention;

FIG. 33 is a schematic diagram describing the operation of the wafer rotation position detection apparatus according to the third embodiment;

FIG. 34 is a schematic diagram describing the operation of the wafer rotation position detection apparatus according to the third embodiment;

FIG. 35 is a block diagram showing the structure of the image process apparatus of the wafer rotation position detection apparatus according to a modification of the third embodiment of the present invention;

FIG. 36 is a block diagram showing the structure of an image process apparatus of a wafer rotation position detection apparatus according to a fourth embodiment of the present invention;

FIG. 37 is a schematic diagram describing the operation of the wafer rotation position detection apparatus according to the fourth embodiment;

FIG. 38 is a schematic diagram describing the operation of the wafer rotation position detection apparatus according to the fourth embodiment;

FIG. 39 is a schematic diagram showing the structure of a sliding portion that slides a photographing device of a wafer rotation position detection apparatus according to a fifth embodiment of the present invention;

FIG. 40 is a schematic diagram describing the operation of the wafer rotation position detection apparatus according to the fifth embodiment;

FIG. 41A and FIG. 41B are schematic diagrams describing an example of which a stage of a wafer rotation position detection apparatus according to a sixth embodiment of the present invention is a θ axis table;

FIG. 42 is a block diagram showing the structure of a single wafer treatment apparatus according to a seventh embodiment of the present invention;

FIG. 43 is a block diagram showing the structure of the single wafer treatment apparatus according to the seventh embodiment of the present invention;

FIG. 44A and FIG. 44B are schematic diagrams describing the operation of a vacuum atmospheric robot of the single wafer treatment apparatus according to the seventh embodiment of the present invention;

FIG. 45 is a schematic diagram showing the relationship between coordinate axes Xw and Yw of a wafer conveyed to the top of a wafer treatment chamber and coordinate axes Xs and Ys of an XY stage of the single wafer treatment apparatus according to the seventh embodiment of the present invention;

FIG. 46 is a schematic diagram showing the case that the angular misalignments of the coordinate axes Xw and Yw and the coordinate axes Xs and Ys of the XY stage operated in the single wafer treatment apparatus according to the seventh embodiment of the present invention are within allowable values;

FIG. 47 is a schematic diagram showing the structure of a wafer position detection apparatus according to an eighth embodiment;

FIG. 48A to FIG. 48D are schematic diagrams showing the structure of the wafer position detection apparatus according to the eighth embodiment;

FIG. 49A and FIG. 49B are schematic diagrams showing the structure of a single wafer treatment apparatus that uses the wafer position detection apparatus according to the eighth embodiment;

FIG. 50 is a schematic diagram showing an observation visual field observed by the position detection apparatus that obtains the center of a wafer;

FIG. 51 is a schematic diagram describing a method of obtaining the center point of a wafer with any three points on an edge of the wafer;

FIG. 52 is a schematic diagram describing a method of obtaining a notch reference point nr with an arc at the bottom of a notch groove of a wafer;

FIG. 53 is a schematic diagram describing the relationship of the position of a wafer on a wafer alignment device, a θ axis stage, and a wafer position detector;

FIG. 54 is a schematic diagram describing a method of obtaining an inclination angle θw of a wafer reference axis Yw of the θ axis stage coordinate system with the center point nr and a notch reference point of a wafer;

FIG. 55 is a schematic diagram describing a method of obtaining a moving direction and a moving amount of the θ axis stage with the rotation angle θw of a wafer;

FIG. 56 is a schematic diagram describing a method of obtaining a moving direction and a moving amount of the θ axis stage with the rotation angle θw of a wafer; and

FIG. 57 is a schematic diagram describing an effect of the wafer alignment apparatus according to the eight embodiment.

### DESCRIPTION OF PREFERRED EMBODIMENTS

Next, with reference to the accompanying drawings, the present invention will be described in detail.

(First Embodiment)

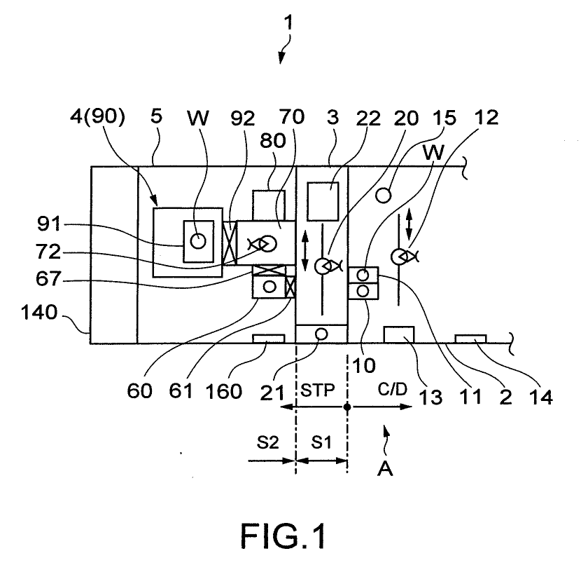

FIG. 1 is a schematic diagram showing the structure of a system of an exposure device as an example of a substrate treatment apparatus according to an embodiment of the present invention. The system of the exposure device 1 can be freely inline-connected to another device such as a resist treatment device 2 (on C/D side in FIG. 1). The resist treatment device 2 has a coating device (coater: COT) that applies resist solution onto a treatment surface of a substrate under treatment for example a semiconductor wafer and a development device (developer: DEV) that develops a resist film formed on the treatment surface of the semiconductor wafer W. In addition, the exposure device 1 has an air aligner section 3 (S1 in FIG. 1) that has a linear space portion as a first unit (interface section) that conveys the semiconductor wafer W under a normal atmosphere (non-reduced pressure atmosphere) and an exposure treatment section 5 (S2 in FIG. 1) as a second unit that has an exposure treatment chamber 4 that performs an exposure treatment for the semiconductor wafer W.

The resist treatment device 2 has a supply section 10 that has a stage with an alignment mechanism. The alignment mechanism physically places a semiconductor wafer W onto the stage, aligns it, and transfers it to the exposure device 1. In addition, the resist treatment device 2 has a reception section 11 that has a stage with an alignment mechanism. The alignment mechanism that can freely receive a semiconductor wafer W physically places it onto the stage and aligns it. The resist treatment device 2 also has a mobile conveyance mechanism 12 that can freely convey a semiconductor wafer W to the supply section 10 and the reception section 11.

A work space area A for a worker is disposed adjacent to the resist treatment device 2. Disposed adjacent to the work space area A are a cassette section 13, in which at least one container for example a cassette that contains a plurality of semiconductor wafers W that the conveyance mechanism 12 can load and unload into and from the cassette, and an operation panel 14 that is an operation mechanism for a control mechanism that controls the resist treatment device 2.

The resist treatment device 2 has an alignment mechanism 15 into and from which a semiconductor wafer W can be loaded and unloaded by the conveyance mechanism 12 and that aligns a semiconductor wafer W that will be transferred to the supply section 10 and/or that has been received from the reception section 11 with a cut portion for example a notch portion or an orientation flat of the semiconductor wafer W. The alignment mechanism 15 is disposed in the resist treatment device 2 opposite to the work space area A (namely, in a non-work space area).

Disposed in the air aligner section 3 (S1 shown in FIG. 1) is a mobile conveyance mechanism 20 that can freely convey a semiconductor wafer W to the supply section 10 and the reception section 11 of the resist treatment device 2. Disposed in the air aligner section 3 (S1 shown in FIG. 1) adjacent to the work space area A is an alignment mechanism 21 into and from which a semiconductor wafer W can be freely loaded by a conveyance mechanism 20 and that aligns a semiconductor wafer W received from the supply section 10 of the resist treatment device 2 through the mobile conveyance mechanism 20 or/and a semiconductor wafer W that will be conveyed to the reception section 11 by conveyance mechanism 20 with a cut portion for example a notch of the semiconductor wafer W.

The alignment of a semiconductor wafer W in the exposure treatment is important from a point of view of the yield. Thus, these alignment mechanisms are structured so that they satisfy the condition of which the alignment accuracy of the alignment mechanism 21 is higher than that of the alignment mechanism 15 of the resist treatment device 2 or/and the alignment accuracy of the supply section 10 or the reception section 11 of the resist treatment device 2 that physically places the semiconductor wafer W onto the stage.

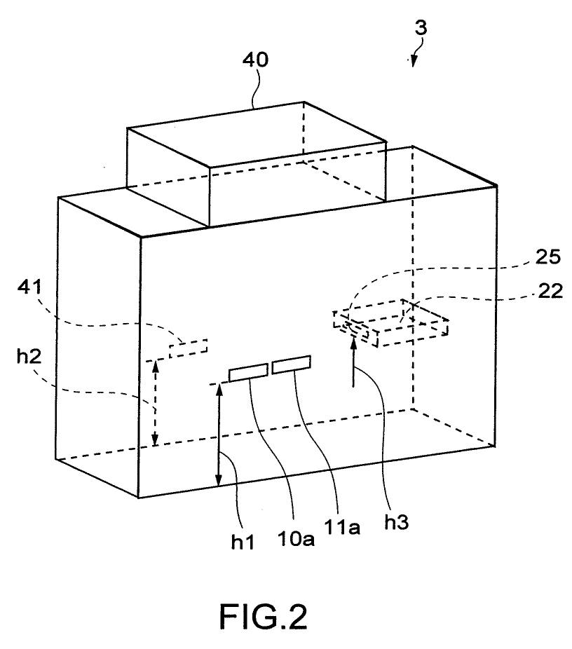

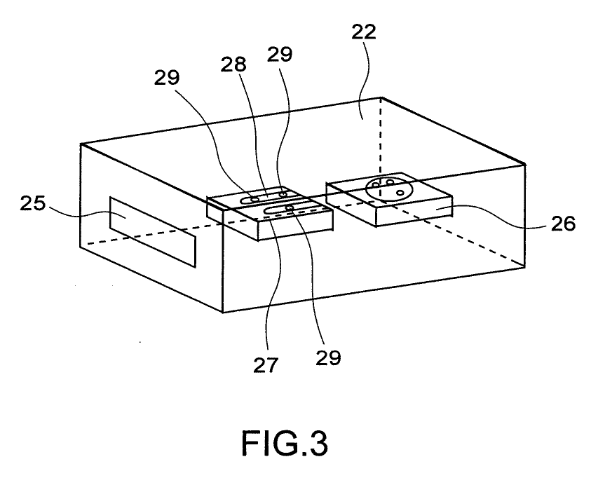

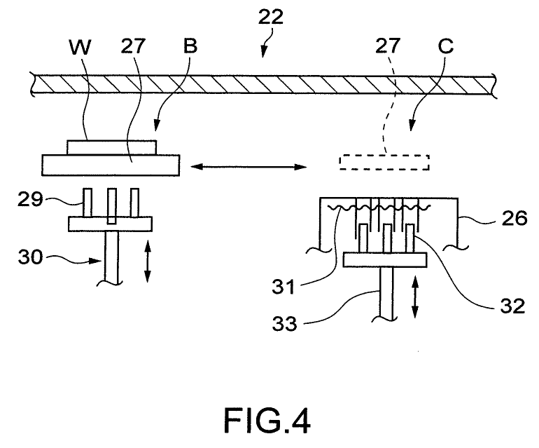

As will be shown in FIGS. 2, 3, and 4, the air aligner section 3 (S1 shown in FIG. 1) has a heat treatment section 22 opposite the work space area A. The heat treatment section 22 performs a post exposure bake (PEB) treatment as a heat treatment for a semiconductor wafer W for which an exposure treatment has been performed by the exposure treatment section 5.

The heat treatment section 22 has a loading/unloading opening 25 through which a semiconductor wafer W is loaded and unloaded. Disposed in the heat treatment section 22 are a heat plate 26 as a heat treatment mechanism that performs a heat treatment for a semiconductor wafer W at for example a predetermined temperature in the range from 75° C. to 650° C., a predetermined temperature in the range from 120° C. to 300° C., for example 250° C. by a heat generation mechanism for example a heater 31; and a temperature adjustment plate 27 as a temperature treatment mechanism that keeps a predetermined temperature, for example, a room temperature of the air aligner section 3, a predetermined temperature that is the same as the room temperature of the resist treatment device 2, for example 23° C.

Although the temperature adjustment plate 27 adjusts the temperature of a semiconductor wafer W before and after it is conveyed to the heat plate 26, the temperature adjustment plate 27 may adjust the temperature of a semiconductor wafer W that has been received by the conveyance mechanism 20 from the supply section 10 of the resist treatment device 2 or/and a semiconductor wafer W that will be conveyed to the reception section 11 of the resist treatment device 2 by the conveyance mechanism 20. Instead, the temperature adjustment plate 27 may adjust the temperature of a semiconductor wafer W before or/and after it is conveyed to the alignment mechanism 21.

The temperature adjustment plate 27 has a support mechanism 30. The temperature adjustment plate 27 is horizontally movable between a standby position B and an operation position C of the heat plate 26 by a moving mechanism (not shown). The support mechanism 30 has a plurality of for example three support pins 29 that protrudes and point-support a semiconductor wafer W through a cut portion 28 of the temperature adjustment plate 27 at the standby position of the temperature adjustment plate 27. The support mechanism 30 can raise and lower the semiconductor wafer W.

The heat plate 26 has a support mechanism 33 that has a plurality of for example three support pins 32 that upwardly protrude and point-support the bottom of the semiconductor wafer W. Thus, the semiconductor wafer W that is loaded through the loading/unloading opening 25 by the conveyance mechanism 20 is received at the top position of the support mechanism 30. The semiconductor wafer W is supported with the support pins 29. When the support pins 29 are lowered, the semiconductor wafer W on the support pins 29 is transferred onto the temperature adjustment plate 27.

After the temperature adjustment plate 27 is moved above the heat treatment section 22, the support mechanism 33 is raised. The semiconductor wafer W placed on the temperature adjustment plate 27 is supported by the support pins 32. Thereafter, when or after the temperature adjustment plate 27 is moved to the standby position, the support mechanism 33 is lowered and the semiconductor wafer W is transferred onto the heat plate 26.

Disposed above the air aligner section 3 (S1 shown in FIG. 1) is a fan filter unit 40 (FFU) as shown in FIG. 2. The FFU 40 generates a down flow of clean air controlled at a predetermined temperature, a predetermined humidity, or/and a predetermined concentration of a chemical component for example 1 ppb or lower of amine by a filter mechanism (not shown) so that the inside of the air aligner section 3 is kept at a predetermined pressure.

Next, an example of a method of reducing the occurrence of cross contamination in the air aligner section 3 (S1 shown in FIG. 1) will be described.

When the height of a supply section loading opening 10a that is a loading opening for a semiconductor wafer W from the supply section 10 of the resist treatment device 2 and the height of a reception section unloading opening 11a as an unloading opening for a semiconductor wafer W to the reception section 11 are denoted by h1; the height of a loading/unloading opening 41 as a loading/unloading opening for a semiconductor wafer W into and from the exposure treatment section 5 is denoted by h2; and the height of a loading/unloading opening 25 through which a semiconductor wafer W is loaded and unloaded into and from the heat treatment section 22 is dented by h3, since the exposure treatment section 5 is also placed under a reduced pressure atmosphere and the exposure treatment section 5 needs to have higher cleanliness for particles than the treatment environment of the resist treatment device 2, these opening are formed so that the condition of h2≧h1, preferably h2>h1, is satisfied. To prevent heat from the loading/unloading opening 25 of the heat treatment section 22 from affecting other sections, the openings are formed so that the condition of h3≧(h1 or h2), preferably h3>(h1 or h2), is satisfied. When the height of the supply section loading opening 10a or/and the reception section unloading opening 11a is(are) nearly the same as the height of the loading/unloading opening 41, it is preferred that the positions of these openings do not fully correspond to each other, but they slightly vary.

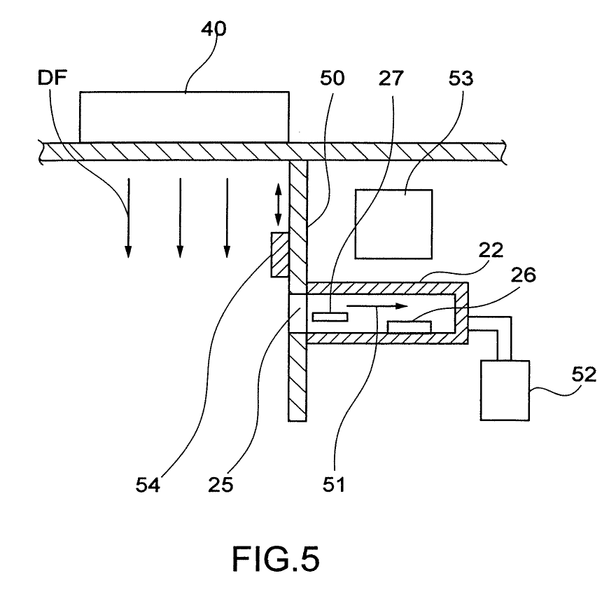

Next, with reference to FIG. 5, an example of a method of suppressing the influence of heat from the loading/unloading opening 25 of the heat treatment section 22 will be described.

A wall 50 is disposed above and below the loading/unloading opening 25 through which a semiconductor wafer W is loaded and unloaded into and from the heat treatment section 22. The wall 50 shields the atmosphere of the heat treatment section 22 and the atmosphere of the conveyance mechanism 20. A flow 51 of air in the heat treatment section 22 is formed from the temperature adjustment plate 27 to the heat plate 26 by an exhaust mechanism for example a vacuum pump 52.

An opening/closing mechanism 54 that opens and closes the opening portion of the loading/unloading opening 25 prevents heat from escaping. This structure allows the area of a down flow DF in the air aligner section 3 to decrease. As a result, the size of the FFU 40 can be decreased. Thus, the size of the system can be decreased. The footprint of the apparatus can be decreased. In addition, the cost of the apparatus can be decreased. Moreover, when a control mechanism (or/and a heat generation mechanism such as a power supply mechanism) of the heat treatment section 22 is disposed above the heat treatment section 22, the influence of heat against a semiconductor wafer W in the air aligner section 3 is further suppressed.

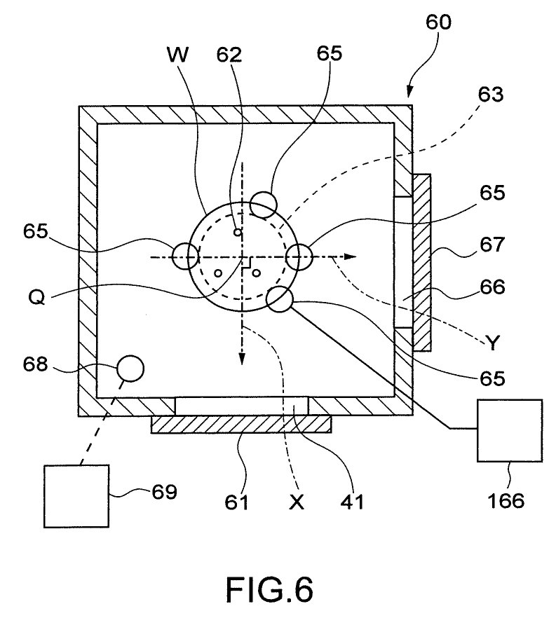

As shown in FIG. 6, a vacuum atmosphere preparation chamber 60 as a substrate loading/unloading section into and from which a semiconductor wafer W is loaded by the conveyance mechanism 20 through the loading/unloading opening 41 is disposed in the exposure treatment section 5. An opening/closing mechanism 61 that air-tightly opens and closes the inside of the vacuum atmosphere preparation chamber 60 is disposed at the loading/unloading opening 41 of the vacuum atmosphere preparation chamber 60. The vacuum atmosphere preparation chamber 60 has a hold table 63 that has a support mechanism (not shown). The support mechanism has a plurality of for example three support pins 62 that upwardly protrude and point-support a semiconductor wafer W so that it can be freely transferred from and to the conveyance mechanism 20.

At least one image detection mechanism, for example a plurality of CCD cameras 65, is disposed above a semiconductor wafer W placed on the hold table 63. The CCD cameras 65 can freely detect images of at least a peripheral portion of a semiconductor wafer W. The CCD cameras 65 are disposed so as to detect at least a position angle θ of the semiconductor wafer W. At least one CCD camera 65, preferably two CCD cameras 65, are disposed on the Y axis that is perpendicular to the conveying direction, X axis, of the semiconductor wafer W by the conveyance mechanism 20 and at least one CCD camera 65 is disposed at another position on the outer periphery of the semiconductor wafer W. Thus, data registered according to reference coordinates of the position angle θ and the X and Y axes and the detected data are compared. The difference is calculated and detected by a control mechanism 166. In FIG. 6, Q represents the center position of the semiconductor wafer W.

A conveying opening 66 through which a semiconductor wafer W is conveyed to a reduced pressure atmosphere conveyance chamber (that will be described later) is disposed in the Y axis direction of the vacuum atmosphere preparation chamber 60. An opening/closing mechanism 67 that can air-tightly open and close the conveying opening 66 is disposed in the conveying opening 66. In addition, the vacuum atmosphere preparation chamber 60 has an exhaust opening 68 through which air is exhausted from the vacuum atmosphere preparation chamber 60 by an exhaust mechanism for example an exhaust pump 69. Thus, the supply amount of inert gas for example nitrogen gas supplied from a gas supply mechanism (not shown) and the exhaust amount of the exhaust pump 69 are controlled so that a pressure between a predetermined vacuum degree and normal atmosphere can be freely set.

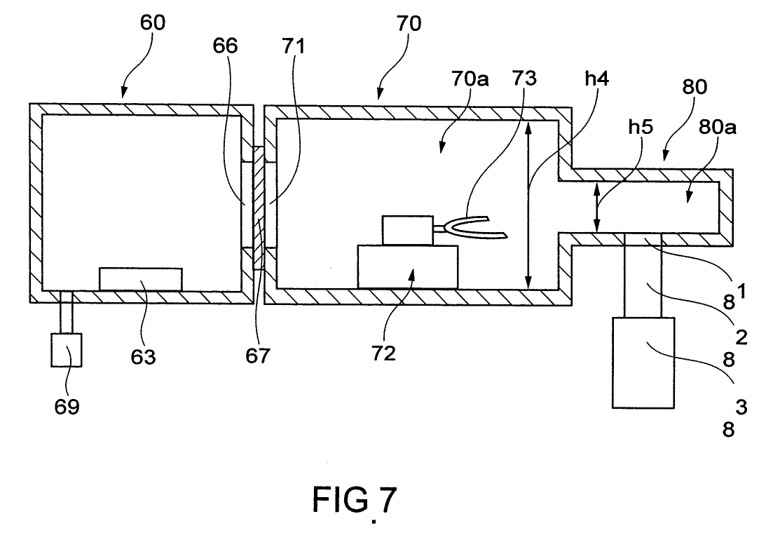

Next, with reference to FIG. 1 and FIG. 7, a reduced pressure atmosphere conveyance chamber 70 will be described. The reduced pressure atmosphere conveyance chamber 70 has a conveyance mechanism 72 that conveys a semiconductor wafer W to the vacuum atmosphere preparation chamber 60 through a conveying opening 71. The conveyance mechanism 72 has an arm 73 as a support mechanism that surface-supports a peripheral portion of the semiconductor wafer W with at least one position or/and point-supports the rear surface of the semiconductor wafer W with a plurality of points.

Disposed adjacent to the reduced pressure atmosphere conveyance chamber 70 and opposite to the vacuum atmosphere preparation chamber 60 is an exhaust chamber 80. The atmosphere of the reduced pressure atmosphere conveyance chamber 70 is connected to the exhaust chamber 80. Disposed below the exhaust chamber 80 is an exhausting opening 81. An exhaust mechanism for example a vacuum pump 83 can totally exhaust gas from not only the exhaust chamber 80 but the reduced pressure atmosphere conveyance chamber 70 through the exhausting opening 81 and an exhaust path 82.

Thus, no exhaust means is directly connected to the reduced pressure atmosphere conveyance chamber 70. When the reduced pressure atmosphere conveyance chamber 70 has the conveyance mechanism 72 and is connected to the exhaust mechanism, the reduced pressure atmosphere conveyance chamber 70 becomes large. Thus, this structure prevents the size of the reduced pressure atmosphere conveyance chamber 70 from increasing. As a result, the size and thickness of the reduced pressure atmosphere conveyance chamber 70 can be decreased. In addition, when the exhaust chamber 80 is detachably structured for repair word for the vacuum pump 83 and maintenance work for the exhaust path 82, the maintenance time can be shortened. In addition, the reduced pressure conveying chamber 70 and the exhaust chamber 80 are structured so that the condition of a capacity 70a of the reduced pressure atmosphere conveyance chamber 70 and a capacity 80a of the exhaust chamber 80 satisfies the condition of capacity 70a≧capacity 80a, preferably, capacity 70a>capacity 80a. Thus, the throughput of maintenance of a predetermined vacuum degree in the reduced pressure atmosphere conveyance chamber 70 can be improved. In addition, the reduced pressure conveying chamber 70 and the exhaust chamber 80 are structured so that a height h4 of a space portion of the reduced pressure conveying chamber 70 is larger than a height h5 of a space portion of the exhaust chamber 80. As a result, gas can be quickly exhausted from the exhaust chamber 80.

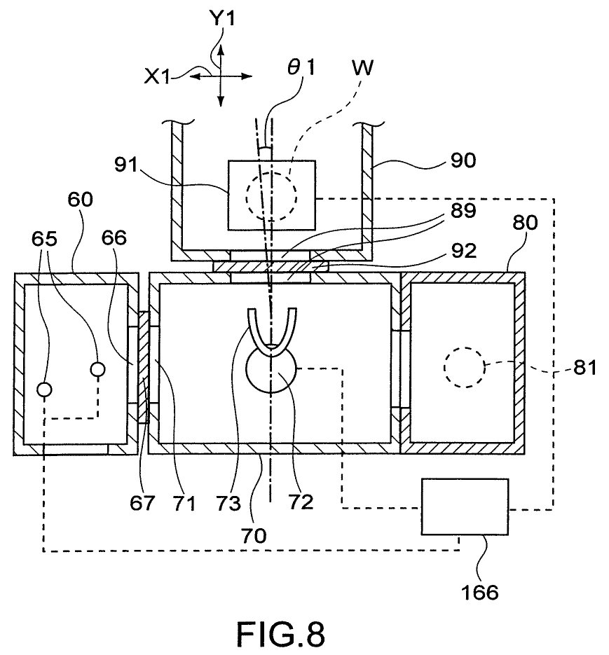

As shown in FIG. 8, the conveyance mechanism 72 of the reduced pressure atmosphere conveyance chamber 70 is controlled by the control mechanism 166. When there is a difference in a calculation result for data captured by the CCD cameras 65, a loading angle θ1 of the arm 73 for the semiconductor wafer W into an exposure treatment chamber 90 is varied and compensated according to the information of the difference (position adjustment by rotating operation). The semiconductor wafer W is conveyed to a stage 91 in the exposure treatment chamber 90 that is kept under a reduced pressure atmosphere through a loading opening 89. The loading openings 89 of the reduced pressure atmosphere conveyance chamber 70 and the exposure treatment chamber 90 can be air-tightly opened and closed by an opening/closing mechanism 92.

In addition, the stage 91 in the exposure treatment chamber 90 can freely move a semiconductor wafer W in an X1 axis direction (left and right directions shown in FIG. 8) and a Y1 axis direction (up and down directions shown in FIG. 8). When there is a difference in a calculation result of data of the CCD cameras 65, the semiconductor wafer W on the stage 91 is horizontally aligned on the X axis and the Y axis by the control mechanism 166 according to the information of the difference.

When the loading angle θ1 of the arm 73 for the semiconductor wafer W into the exposure treatment chamber 90 is varied and the semiconductor wafer W is loaded into the exposure treatment chamber 90 with the varied loading angle θ1, the stage 91 in the exposure treatment chamber 90 is moved according to data of the transfer position of the arm 73 for the semiconductor wafer W predicted by the control mechanism 166.

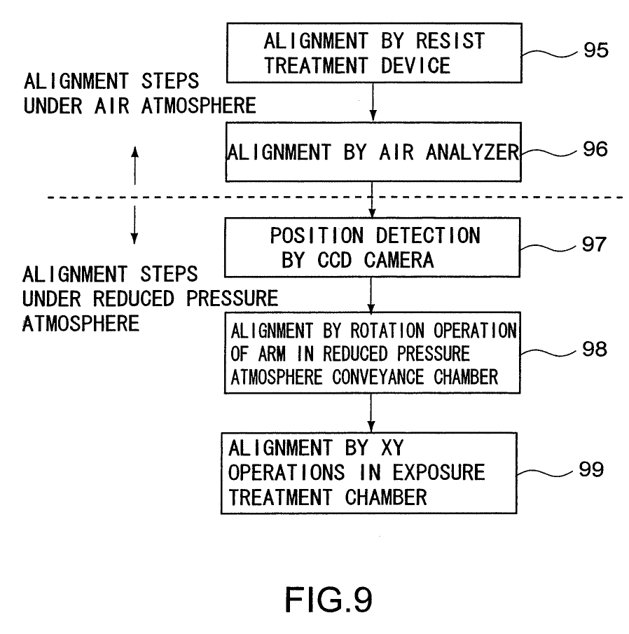

As shown in FIG. 9, there are alignment steps for a semiconductor wafer W. At step 95, the semiconductor wafer W is aligned by the resist treatment device 2 as another device. At step 96, the semiconductor wafer W is aligned by the air aligner section 3. These steps are preformed under an air atmosphere. Thereafter, at step 97, the position of the semiconductor wafer W is detected by the CCD cameras 65 in the vacuum atmosphere preparation chamber 60 under a reduced pressure atmosphere. At step 98, while the rotation angle of the arm 73 in the reduced pressure conveying chamber 70 is being adjusted according to position detection data detected by the CCD cameras 65, the semiconductor wafer W is conveyed and aligned. Thereafter, at step 99, the semiconductor wafer W is aligned by moving the X and Y axes of the semiconductor wafer W on the stage 91 in the exposure treatment chamber 90 as another reduced pressure atmosphere chamber. In this manner, since the semiconductor wafer W is aligned at a plurality of positions under an air atmosphere. The position of the semiconductor wafer W is detected under a reduced gas atmosphere. The semiconductor wafer W is aligned at a plurality of positions under a reduced pressure atmosphere. Thus, the alignment accuracy for the semiconductor wafer W is improved.

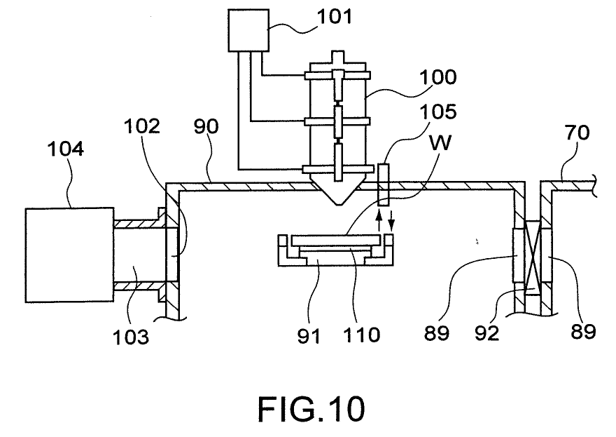

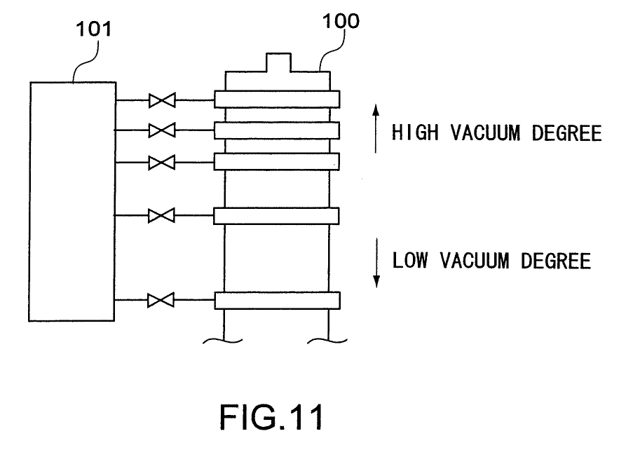

As shown in FIG. 10, in the exposure treatment chamber 90, a column 100 is disposed at a ceiling portion. The column 100 is a an electron beam emission mechanism that emits an electron beam to a semiconductor wafer W placed on the stage 91. The column 100 has an electron gun as a source of an electron beam and an ion pump as an example of an exhaust mechanism for example an ion pump 101 that causes the inner pressure of the electron gun section to become a ultra high vacuum degree. FIG. 11 shows the structure of the exhaust lines of the column 100 and settings of vacuum degrees. As the structure of the exhaust lines of the column 100, gas is exhausted from a plurality of positions in the vertical direction. Thus, the vacuum degree is substantially proportional to the distance from the bottom of the column 100. This structure allows straight traveling efficiency of an electron beam to improve or prevents energy from lowering.

As shown in FIG. 10, an exhaust opening 102 is disposed in a side wall of the exposure treatment chamber 90 on the opposite side of the reduced pressure atmosphere conveyance chamber 70. An exhaust mechanism for example a highly vacuum pump (turbo-molecular pump) 104 that exhausts gas from the exposure treatment chamber 90 is disposed through an exhaust line 103. A mark detection mechanism 105 that optically checks a mark formed on a treatment surface of a semiconductor wafer W placed on the stage 91 is disposed at a ceiling portion of the exposure treatment chamber 90. When necessary, the semiconductor wafer W is finally aligned by the operations of the XY axes of the stage 91.

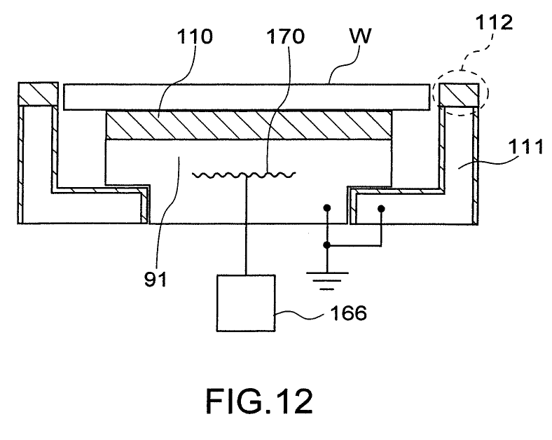

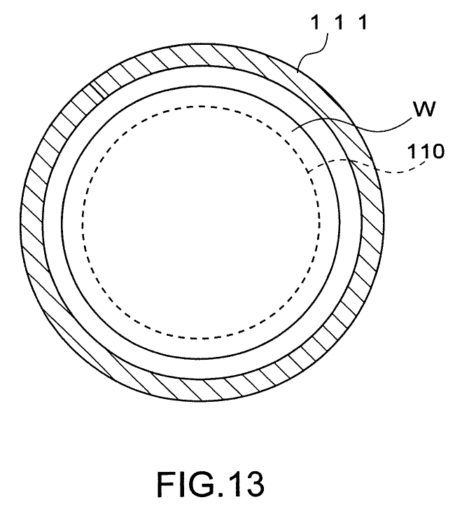

As shown in FIG. 12 and FIG. 13, the stage 91 has a static chuck mechanism 110 that statically chucks a semiconductor wafer W. The stage 91 is made of for example alumina, which is an insulation material. The stage 91 is coated with an electrically conductive material because of the following reasons.

1) light, strong, and non-expansible structural material: the weight of a moving part of the stage can be decreased, the characteristic frequency can be increased, and the thermal expansion can be decreased.

2) Decrease of disturbance against electron beam: when electrons are charged on the front surface of the stage 91, they affect the path of a beam. Thus, the surface exposed to an electron beam is conductively formed so that electrons flow to the ground. When the wall thickness of the conductive member is large, an eddy current occurs and affects the electron beam. Thus, the conductive portion of the front surface of the stage 91 needs to be formed of a thin film.

A ring-shaped member 111 is disposed around the stage 91. The reception section 11 is made of for example alumina, which is an insulation material. The front surface of the ring-shaped member 111 is coated with a conductive material. The height of the outer peripheral portion of the ring-shaped member 111 is almost the same as that of the treatment surface of the semiconductor wafer W chucked by the static chuck mechanism 110 of the stage 91. The ring-shaped member 111 also has a flat portion 112 that is level with the semiconductor wafer W. The front surface of the ring-shaped member 111 is coated with an electron beam refraction protection film that suppresses refraction of an electron beam emitted from the column 100, namely prevents occurrence of an eddy current. The material of the electron beam refraction protection film is for example a titan type material such as a TiN film.

The ring-shaped member 111 and the stage 91 are grounded as shown in FIG. 12.

Disposed on the stage 91 is also a heating mechanism for example a heater 170. The control mechanism 166 can freely set a semiconductor wafer W placed on the stage 91 at a predetermined temperature along with a cooling mechanism (not shown). The predetermined temperature is lower than the temperature of the semiconductor wafer W when a treatment section of the resist treatment device 2 performs a treatment for the semiconductor wafer W, for example, the coating device (coater: COT) applies resist solution onto the semiconductor wafer W, the inner atmospheric temperature of the resist treatment device 2 or/and the inner atmospheric temperature of the air aligner section 3 by a fragment of 1° C. to 3° C., preferably, 0.1° C. to 0.5° C. This temperature setting prevents the resist film formed on the semiconductor wafer W from expanding and shrinking. As a result, this temperature setting prevents the accuracy of the exposure treatment from deteriorating. When air is vacuum exhausted in a load lock chamber (for example, the vacuum atmosphere preparation chamber 60 or the like), since heat is depleted from a semiconductor wafer W, the temperature of the semiconductor wafer W that has been just conveyed to the stage tends to be lower than the temperature of the semiconductor wafer W that has been loaded into the load lock chamber such as the air aligner section 3. Thus, when the temperature of the stage is lowered for which the temperature of the semiconductor wafer W is decreased by the vacuum exhaust, it is not necessary to wait until the temperature of the semiconductor wafer W becomes stable (expansion converges).

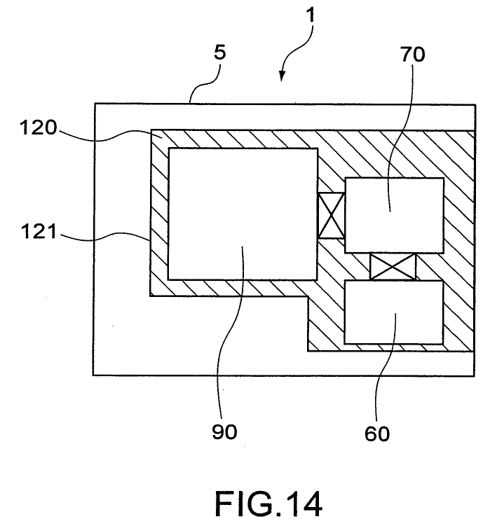

FIG. 14 shows the structure that shields the exposure treatment chamber 90, which performs an exposure treatment emitting an electron beam onto a semiconductor wafer W, from a magnetic field. As shown in FIG. 14, the exposure treatment chamber 90, the reduced pressure atmosphere conveyance chamber 70, and the vacuum atmosphere preparation chamber 60 are surrounded by a magnetization suppression mechanism, for example a magnetic shield member 121 made of for example Permalloy (trademark), electromagnetic soft iron, electromagnetic steel, Sendust (trademark), ferrite, or the like. This is because an electron beam is deflected by an external magnetic field. The magnetic shield member 121 prevents the yield of the exposure treatment for a semiconductor wafer W to decreasing. Although it is ideal to surround the whole apparatus with the magnetic shield member, it is not practical. In addition, since the apparatus has a magnetic field generation source such as a control device, it is preferred to surround the exposure treatment chamber 90, the reduced pressure atmosphere conveyance chamber 70, and the vacuum atmosphere preparation chamber 60 with the magnetic shield member 121. It is possible to surround only the exposure treatment chamber 90 with the magnetic shield member 121. In this case, however, the exposure treatment chamber 90 cannot be sufficiently prevented from being magnetized with magnetic fields of the reduced pressure atmosphere conveyance chamber 70 and the vacuum atmosphere preparation chamber 60. Thus, it is necessary to surround at least the exposure treatment chamber 90 and the reduced pressure atmosphere conveyance chamber 70 with the magnetic shield member 121, preferably the exposure treatment chamber 90, the reduced pressure atmosphere conveyance chamber 70, and the vacuum atmosphere preparation chamber 60 with the magnetic shield member 121.

Thus, an area 120 of the substantial floor area of the apparatus is coated with the magnetic shield member 121. The area 120 is larger than the half of the whole floor area and smaller than the whole floor area. In addition, it is preferred that the thickness and structure of the magnetic shield member 121 be selected so that as the magnetic field suppression effect of the magnetic shield member 121, the intensity of the magnetic field outside the magnetic shield member 121 is ½ or lower than that of the magnetic field inside the magnetic shield member 121.

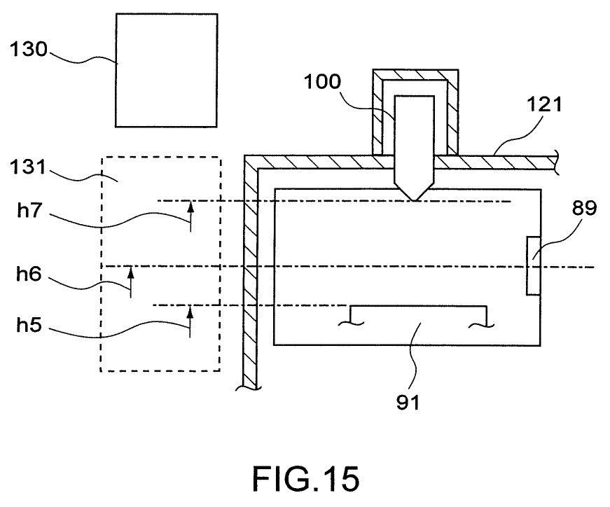

FIG. 15 shows a power supply section as an energy source that generates an electron beam, for example, an amplifier section 130 that is one of magnetic field generation sources. The amplifier section 130 is disposed in the exposure treatment chamber 90 opposite to the reduced pressure atmosphere conveyance chamber 70. The height of the amplifier section 130 is larger than a height h5 of a semiconductor wafer W on the stage 91, preferably larger than a height h6 of the loading opening 89 as a conveying opening for the semiconductor wafer W in the exposure treatment chamber 90, more preferably, larger than a height h7 of an electron beam emitted from the column 100. These heights are considered for an influence to an electron beam used for a treatment with an electromagnetic wave generated by the amplifier section 130.

Disposed below the amplifier section 130 is a maintenance space section 131 in which a worker performs maintenance work for the exposure treatment chamber 90 and so forth. Thus, in consideration of not only the influence of electromagnetic wave, but work efficiency of the maintenance work, the space of the apparatus can be effectively used. As a result, the size of the apparatus can be decreased. In addition, the footprint of the apparatus can be decreased.

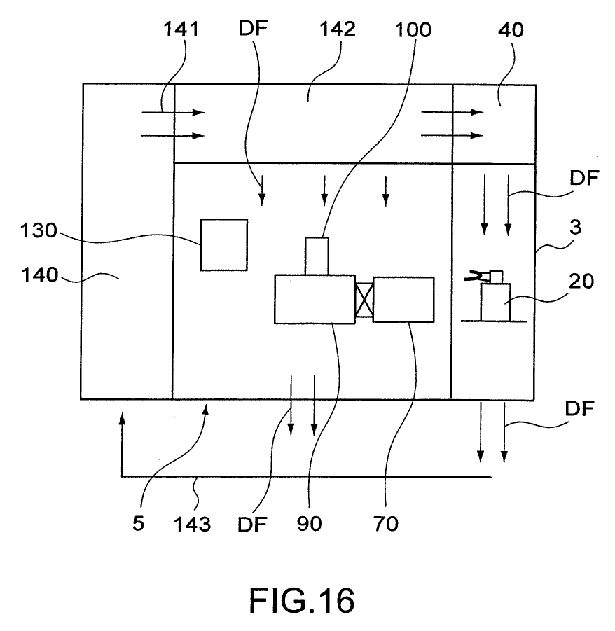

FIG. 16 shows a gas supply mechanism 140 that is disposed in the exposure treatment section 5 opposite to the air aligner section 3. The gas supply mechanism 140 supplies gas that has been controlled for at least temperature or humidity, for example clean air 141 to the whole apparatus. The gas supply mechanism 140 also supplies the clean air 141 to the FFU 40 through an air flow path 142 disposed above the exposure treatment section 5.

In addition, the gas supply mechanism 140 supplies the clean air 141 from the air flow path 142 to the exposure treatment section 5 at a predetermined flow rate so that a down flow DF takes place in the exposure treatment section 5. The clean air 141 is collected from lower positions of the exposure treatment section 5 and the air aligner section 3. The collected clean air 141 is returned to the gas supply mechanism 140 through an air collection path 143. In such a manner, an effective circulation system is formed.

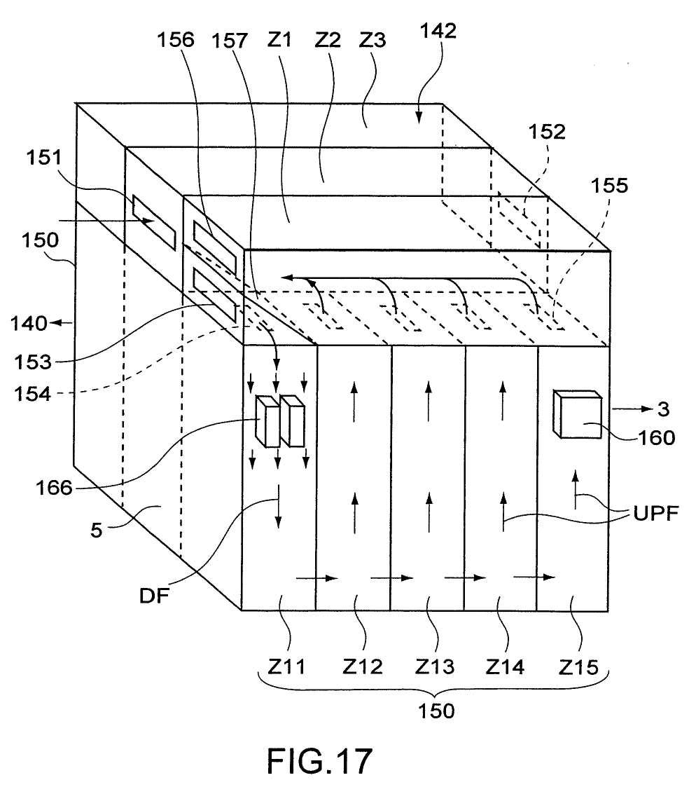

As shown in FIG. 17, the air flow path 142 is horizontally divided into a plurality of zones Z1, Z2, and Z3. In addition, a plurality of air flow paths 150 are formed on both wall sides of the exposure treatment section 5. The air flow paths 150 are vertically divided into a plurality of zones Z11, Z12, Z13, Z14, and Z15. The zone Z2 of the air flow path 142 is a flow path through which clean air is supplied from the gas supply mechanism 140 to the exposure treatment section 5 through an intake opening 151. In addition, the air flow path 142 has an air supply opening 152 through which clean air is supplied to the FFU 40.

Disposed in the zone Z1 and zone Z3 of the air flow path 142 is an air supply opening 153 through which clean air is supplied from the gas supply mechanism 140 to at least one zone of the air flow paths 150, for example, the zone Z11. The supplied clean air is taken from an air intake opening 154 disposed above the flow path of the zone Z11. The taken clean air forms a down flow DF that flows downward.

The down flow DF is guided from a lower position the flow path of the zone Z11 to flow paths of the plurality of zones Z12, Z13, Z14, and Z15. The guided clean air forms up flows UPF in the flow paths of the plurality of zones Z12, Z13, Z14, and Z15 as shown in FIG. 17. The up flows UPF of the plurality of zones Z12, Z13, Z14, and Z15 are collected into the air flow path 142 through air collection openings 155 disposed at upper positions of the flow paths of the plurality of zones Z12, Z13, Z14, and Z15. The collected air is totally collected by the gas supply mechanism 140 through an air collection opening 156. In this manner, an effective circulation system is formed.

A partition plate 157 as a gas partition member is disposed in the flow paths of the zones Z1 and Z3 to form a gas supply path of clean air that flows in the zone Z11 and a gas collection path of clean air that flows from the zones Z12, Z13, Z14, and Z15. In the flow path of the zone Z11, in which the down flow DF is formed, a heat source for example a control mechanism 166 for the exposure treatment section 5 is disposed. In an up flow UPF zone of the zone Z12, Z13, Z14, or Z15, for example the zone 15, an operation mechanism for the control mechanism 166, for example, an operation panel 160 is disposed. The heat generation of the operation panel 160 is smaller than that of the control mechanism 166.

Thus, this magnetic shield prevents the inside of the apparatus from being magnetized. This heat management system prevents the apparatus from being thermally affected and from thermally affecting the outside of the apparatus. It is more preferred that a heat source be disposed in at least one of the up flow UPF zones Z12, Z13, Z14, and Z15 so that heat generated by the heat source rises and is collected. As a result, heat may be prevented from unevenly distributing in the apparatus. In addition, heat may be is prevented from adversely affecting the treatment chambers. Thus, the yield of semiconductor wafers W may be improved.

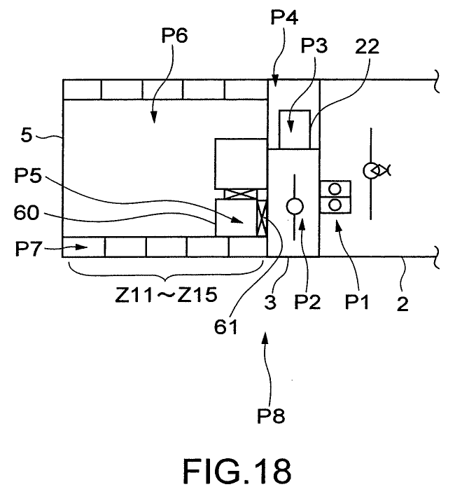

FIG. 18 shows the conditions of pressures in individual sections of the apparatus. When the inner pressure of the resist treatment device 2 is denoted by P1; the inner pressure of the air aligner section 3 is denoted by P2; the inner pressure of the heat treatment section 22 is denoted by P3 (when an opening/closing mechanism is disposed in the heat treatment section and is open); the inner pressure of the heat treatment section 22 is denoted by P4 (clean air may be supplied from the gas supply mechanism 140 to this space or a down flow may be formed by clean air supplied from the FFU 40); the inner pressure of the vacuum atmosphere preparation chamber 60 is denoted by P5 (when the opening/closing mechanism 61 is open); the inner pressure of the exposure treatment section 5 is denoted by P6; the inner pressure of each of the zones Z11, Z12, Z13, Z14, and Z15 is denoted by P7; and the inner pressure of the clean room in which the apparatus is disposed is denoted by P8, these pressures have been set so that then the conditions of P6>P2, P1>P2, P5>P2, P2>P4, P2>P3, and P6≧P7 are satisfied. The conditions of P6>P2, P1>P2, and P5>P2 prevent clean air from flowing from the air aligner section 3 to the treatment chambers of the resist treatment device 2 and the exposure treatment section 5 so as to prevent the treatment environment from being deteriorated and the devices from being cross-contaminated.

When the conditions of P6>P2, P1>P2, and P5>P2 are compared with the inner pressure P8 of the clean room, the condition of P2>P8 is satisfied. In other words, the treatment environment can be prevented from being deteriorated by air of the clean room. Next, the conditions of P2>P4 and P2>P4 will be described. As described above, exhausted gas flows from the temperature adjustment mechanism to the heat treatment mechanism of the heat treatment section 22. This structure prevents heat from adversely affecting the conveyance mechanism. In addition, this structure prevents particles and so forth that take place in a semiconductor wafer W from scattering around the conveyance mechanism.

In addition, since there are heat generation sources such as the power supply section and the control mechanism for the heat treatment at an upper position of the heat treatment section, these inner pressures prevent heat from adversely affecting the conveyance mechanism. Of course, when the conditions of these inner pressures are compared with the inner pressure P8 of the clean room, the conditions of (P2, P4, P3)>P8 need to be satisfied. In addition, it is preferred that the condition of P3≧P4 be satisfied. This condition prevents heat from adversely affecting the heat treatment section 22.

Treatment chambers in the exposure treatment section 5 cause a part of a down flow to change to a horizontal flow. Even if gas is exhausted downward, it is preferred that with the condition of P6≧P7, gas that leaks be collected in the side wall direction because agitation of an air flow is suppressed in the apparatus. This condition considers a situation of which a gap takes place for example a panel is mistakenly removed in maintenance work. When these conditions are compared with the inner pressure P8 of the clean room, the conditions of (P6, P7)>P8 need to be satisfied. These conditions prevent air in the clean room from adversely affecting treatment environment.

In addition, the inner pressures P5, P1, and P2 have been set so that the conditions of P5≧P1>P2 are satisfied. These conditions prevent particles and so forth from entering the vacuum atmosphere preparation chamber 60. When the inner pressure P2 of the air aligner section 3 is compared with the inner pressure P8 of the clean room, the condition of P2>P8 needs to be satisfied.

In addition, the inner pressures have been set so that the condition of which the inner pressure of the vacuum atmosphere preparation chamber 60 (when the opening/closing mechanism 67 is open) is equal to or larger than the inner pressure of the reduced pressure atmosphere conveyance chamber 70 (when the opening/closing mechanism 67 is open), preferably, the inner pressure of the vacuum atmosphere preparation chamber 60 is larger than the inner pressure of reduced pressure atmosphere conveyance chamber 70 is satisfied. In addition, the inner pressures have been set so that the condition of which the inner pressure of the reduced pressure atmosphere conveyance chamber 70 (when the opening/closing mechanism 92 is open) is equal to or larger than the inner pressure of the exposure treatment chamber 90 (when the opening/closing mechanism 92 is open), preferably the exposure treatment chamber 90 is larger than the reduced pressure atmosphere conveyance chamber 70 is satisfied. These conditions allows the reduced pressure atmosphere conveyance chamber 70 to collect particles that take place in the vacuum atmosphere preparation chamber 60 or the exposure treatment chamber 90 and prevent the particles from entering the exposure treatment chamber 90. Thus, these settings improve the yield of substrates under treatments. More preferably, the inner pressures have been set so that the conditions of which the inner pressure of the vacuum atmosphere preparation chamber 60 is larger than the inner pressure of the exposure treatment chamber 90 and the inner pressure of the exposure treatment chamber 90 is larger than the inner pressure of the reduced pressure atmosphere conveyance chamber 70 are satisfied.

The inner atmospheric temperatures have been set so that the condition of which the inner atmospheric temperature of the resist treatment device 2 is equal to or larger than the inner atmospheric temperature of the air aligner section 3, preferably, the inner atmospheric temperature of the resist treatment device 2 is larger than the inner atmospheric temperature of the resist treatment device 2 is satisfied. As described above, the temperature difference is set at a temperature lower than the inner atmospheric temperature of the resist treatment device 2 by a fragment of 1° C. to 3° C., preferably 0.1° C. to 0.5° C. This temperature difference prevents a resist film formed on a semiconductor wafer W from expanding and shrinking and thereby preventing the accuracy of the exposure treatment from deteriorating. When a semiconductor wafer W heated by the temperature adjustment plate 27 for a temperature slightly higher than the temperature of the upper portion of the stage 91 is conveyed to the load lock chamber (vacuum atmosphere preparation chamber 60 or the like) with for example the temperature adjustment plate 27, the temperature drop of the semiconductor wafer W due to the vacuum exhaust in the load lock chamber (vacuum atmosphere preparation chamber 60 or the like) can be offset. In addition, the inner atmospheric temperatures have been set so that the conditions of which the inner atmospheric temperature of the air aligner section 3 is nearly equal to the inner atmospheric temperature of the exposure treatment section 5 and the inner atmospheric temperature of the exposure treatment section 5 is nearly equal to the inner atmospheric temperatures of the zones Z11, Z12, Z13, Z14, and Z15 are satisfied. In this description, the range of “nearly equal to” is within 3° C.

The inner atmospheric humidities have been set so that the conditions of which the inner atmospheric humidity of the air aligner section 3 is nearly equal to the inner atmospheric humidity of the exposure treatment section 5, the inner atmospheric humidity of the exposure treatment section 5 is nearly equal to the inner atmospheric humidities of the zones Z11, Z12, Z13, Z14, and Z15, and the inner atmospheric humidities of the zones Z11, Z12, Z13, Z14, and Z15 are nearly equal to the inner atmospheric humidity of the resist treatment device 2 are satisfied. In addition, the inner atmospheric humidities have been set so that the condition of which the inner atmospheric humidity of the air aligner section 3 is nearly equal to or larger than the inner atmospheric humidity of the vacuum atmosphere preparation chamber 60 (when the opening/closing mechanism 61 is open), preferably, the inner atmospheric humidity of the air aligner section 3 is larger than the inner atmospheric humidity of the vacuum atmosphere preparation chamber 60 (when the opening/closing mechanism 61 is open) is satisfied. Thus, the condition of which the inner atmospheric humidity of which the inner atmospheric humidity of the resist treatment device 2 is grater than the inner atmospheric humidity of the vacuum atmosphere preparation chamber 60 (when the opening/closing mechanism 61 is open) needs to be satisfied. This is because the inside of the vacuum atmosphere preparation chamber 60 is under a reduced pressure atmosphere, humidity causes the throughput of the reduced pressure atmosphere to lower. Thus, it is necessary to cause rare gas for example N2 to flow from the vacuum atmosphere preparation chamber 60 to the air aligner section 3.

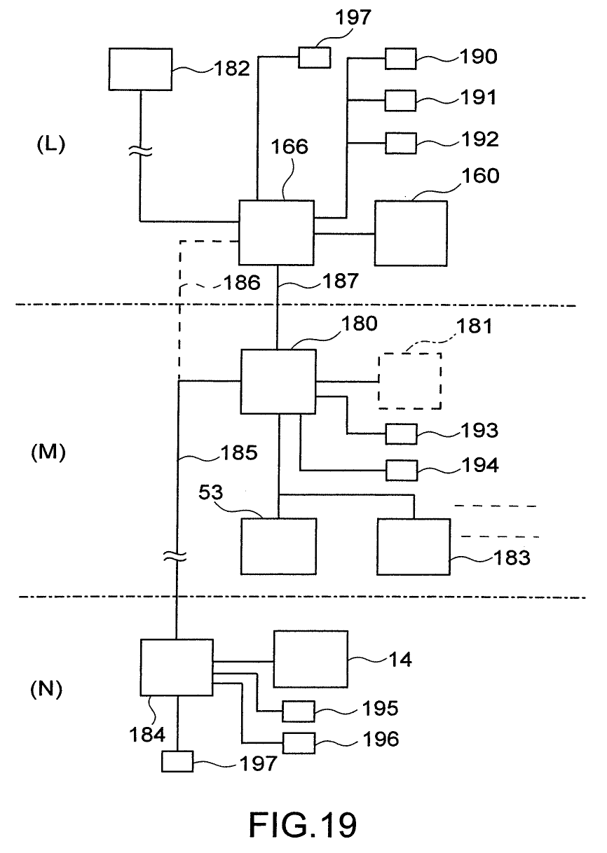

FIG. 19 shows the structure of control signals and the control mechanism. As described above, the control mechanism 166 is disposed in the exposure treatment section 5. In addition, the exposure treatment section 5 has an operation mechanism 160 that has a display mechanism. The control mechanism 166 can control devices of the exposure treatment section 5. The control mechanism 166 can transmit and receive signals to and receive a host computer of a plant in which the apparatus is installed (denoted by L in FIG. 19). In addition, the air aligner section 3 has a control mechanism 180 that controls devices of the air aligner section 3. An operation mechanism 181 that has a display mechanism is connected to the control mechanism 180. If the operation mechanism 160 can be used instead of the operation mechanism 181, it may be omitted. When necessary, the air aligner section 3 may be manufactured, sold, and/or maintained as one independent device so that it can be freely connected to the apparatus for maintenance work.

As described above, the control mechanism 180 transmits and receives signals to and from the control mechanism 53, which controls the heat treatment section. In addition, the control mechanism 180 can transmit and receive signals to and from a control mechanism 183 that controls the conveyance mechanism 20 (denoted by M in FIG. 19). In addition, the control mechanism 180 can transmit and receive signals to and from a control mechanism 184 of the resist treatment device 2 through a signal line 185. In addition, the control mechanism 184 is connected to the operation panel 14 that has a display mechanism. Signals transmitted and received to and from the resist treatment device 2 are signals that take place when a semiconductor wafer W is transferred between the conveyance mechanism 20 and the supply section 10 or the reception section 11 of the resist treatment device 2 and signals with respect to atmospheric pressures in the resist treatment device 2.

Signals about inner atmospheric pressures may be transmitted from the air aligner section 3 to the control mechanism 184 of the resist treatment device 2 through the control mechanism 180 so that the control mechanism 180 and 184 can mutually check inner atmospheric pressures of the air aligner section 3. With this information, the control mechanism 166 controls the atmospheric pressures of the whole apparatus. In this example, the control mechanism 180 and the control mechanism 184 were described. Instead, the control mechanism 166 may receive a signal from the control mechanism 184 through a signal line 186. The control mechanism 166 may send a command to the control mechanism 180 to control it.

In addition, although the control mechanism 166 and the control mechanism 180 transmit and receive signals through a signal line 187, since the control mechanism 166 controls the whole apparatus, the control mechanism 166 can receive signals that represent individual functions of the air aligner section 3 as information transmitted from the control mechanism 180 to the control mechanism 166. One of important signals transmitted from the control mechanism 166 to the control mechanism 180 is used to manage start time of the heat treatment that the control mechanism 180 causes the control mechanism 53 to start according to start time or end time of the exposure treatment of the exposure treatment chamber 90 for a semiconductor wafer W.

The time management from the exposure treatment to the PEB exposure treatment is important because the state of a resist film formed on a semiconductor wafer W chronologically varies that causes the yield of semiconductor wafers W to decrease. Thus, since the control mechanism 166 that manages the whole exposure device issues this command, the yield of semiconductor wafers W can be prevented from lowering.

Since a resist film formed on a semiconductor wafer W chronologically varies, the control mechanism 184 of the resist treatment device 2 informs the control mechanism 180 of the end time of the resist coating. The control mechanism 184 informs the control mechanism 166 of time information of a conveyance time period in the air aligner section 3. The control mechanism 166 considers conveyance time periods or/and variation factors of a resist film in the reduced pressure atmosphere conveyance chamber 70, the vacuum atmosphere preparation chamber 60, and the exposure treatment chamber 90 and causes the exposure treatment chamber 90 to perform the exposure treatment for a semiconductor wafer W. After the exposure treatment chamber 90 has preformed the exposure treatment for the semiconductor wafer W, the control mechanism 180 considers change factors of the resist film formed on the semiconductor wafer W for which the exposure treatment has been performed and manages times such as start time for the PEB heat treatment according to information received from the control mechanism 166.

The control mechanism 180 transmits information about a time at which a semiconductor wafer W will be transferred to the resist treatment device 2 to the control mechanism 184 according to the end time of the PEB heat treatment. The control mechanism 184 manages times for a semiconductor wafer W such as start time for the development treatment for a resist film formed on a semiconductor wafer W. As a result, a plurality of semiconductor wafers W can be prevented from differing in the development treatment. Thus, the yield of semiconductor wafers W can be improved. In the foregoing, functions of the control mechanism 180 were described. Of course, the control mechanism 166 may perform part of functions of the control mechanism 180. These information is stored in a storage mechanism of each control mechanism for example a volatile memory or a CD-R. The stored information can be displayed by the display mechanism of each operation mechanism.

The control mechanism 166 or the control mechanism 180 can transmit information about times such as end time of the PEB heat treatment in the air aligner section 3 or/and information about inner atmospheres in the air aligner section 3 to the control mechanism 184. The control mechanism 184 can manage development start time. As a result, the yield of semiconductor wafers W can be improved. The control mechanism 166 or the control mechanism 180 receives information about time at which resist solution has been applied, information about time at which the heat treatment has been performed, or information about heat in the heat treatment and manages start time of the exposure treatment.

Connected to the control mechanism 166 are a pressure detection mechanism for example a pressure sensor 190 that detects the inner pressure of a predetermined section in the exposure treatment section 5, a pressure detection mechanism for example a pressure sensor group 191 that detects the internal pressures of predetermined portions of the zones Z11, Z12, Z13, Z14, and Z15, and a pressure detection mechanism for example a pressure sensor 192 that detects the inner pressure of a predetermined section in the vacuum atmosphere preparation chamber 60. Connected to the control mechanism 180 are a pressure detection mechanism for example a pressure sensor 193 that detects the inner pressure of a predetermined section of the air aligner section 3 and a chemical detection mechanism 194 that detects a chemical component for example ammonium of a predetermined section in the air aligner section 3. Connected to the control mechanism 184 are a pressure detection mechanism for example a pressure sensor 195 that detects the inner pressure of a predetermined section in the resist treatment device 2 and a chemical detection mechanism 196 that detects a chemical component for example ammonium of a predetermined section in the resist treatment device 2.

Connected to the control mechanism 166 or/and the control mechanism 184 is also a pressure detection mechanism for example a pressure sensor 197 that detects the inner pressure of the clean room in which the apparatus is disposed. In such a manner, the inner pressure and so forth of each section can be monitored. In the resist treatment device 2 and the air aligner section 3, their chemical detection mechanisms monitor chemical components because these chemical components severely affect the treatments for a semiconductor wafer W in the treatment sections of the resist treatment device 2. Thus, it is necessary to monitor chemical components not only in the resist treatment device 2, but in the air aligner section 3.

The substrate treatment apparatus according to an embodiment of the present invention is structured as described above.

Next, the operations of the treatments for a semiconductor wafer W will be described.

Firstly, in the resist treatment device 2, the coating device (coater: COT) that applies resist solution onto a treatment surface of a semiconductor wafer W. Thereafter, a heat treatment is performed for the semiconductor wafer W at a predetermined that is nearly the same temperature as the inner atmospheric temperature of the resist treatment device 2. Thereafter, the semiconductor wafer W is conveyed to the alignment mechanism 15 by the conveyance mechanism 12. Thereafter, the alignment mechanism 15 aligns the semiconductor wafer W (referred to as the first alignment in the resist treatment device 2). Thereafter, the semiconductor wafer W is conveyed to the supply section 10 by the conveyance mechanism 12. The supply section 10 aligns the semiconductor wafer W by physically dropping the semiconductor wafer W (referred to as the second alignment in the resist treatment device 2). After the control mechanism 184 has detected the semiconductor wafer W on the supply section 10 with a sensor, the control mechanism 184 transmits a “conveyance ready” signal to the control mechanism 166 or/and the control mechanism 180.

When the control mechanism 166 or/and the control mechanism 180 has received the signal, they receive the semiconductor wafer W from the supply section 10 through the conveyance mechanism 20, detects the semiconductor wafer W with a sensor of the conveyance mechanism 20, and transmits a “conveyance completion” signal to the control mechanism 184. During this operation, the conveyance mechanism 20 coveys the semiconductor wafer W to the alignment mechanism 21. The alignment mechanism 21 aligns the semiconductor wafer W (referred to as the alignment in the air aligner section 3). During the conveyance step, the temperature of the semiconductor wafer W is lowered to the inner atmospheric temperature of the air aligner section 3 so that the temperature of the semiconductor wafer W becomes nearly the same as or lower than the inner atmospheric temperature of the resist treatment device 2.

After the foregoing step, the conveyance mechanism 20 conveys the semiconductor wafer W to the vacuum atmosphere preparation chamber 60, which is a substrate loading/unloading section of the exposure treatment section 5. The vacuum atmosphere preparation chamber 60 exhausts gas from the chamber to decrease a positive pressure higher than the inner atmosphere pressure of the air aligner section 3 to a predetermined reduced pressure (this reduced pressure is nearly the same as a pressure at which the semiconductor wafer W is transferred with the reduced pressure atmosphere conveyance chamber 70 (the inner pressures of the vacuum atmosphere preparation chamber 60 and the reduced pressure conveying chamber 70 may be set so that the inner pressure of the vacuum atmosphere preparation chamber 60 is slightly lower than the inner pressure of the reduced pressure atmosphere conveyance chamber 70 to prevent particles from entering the reduced pressure atmosphere conveyance chamber 70). After gas has been exhausted or while it is being exhausted, the position of the semiconductor wafer W is monitored by a plurality of CCD cameras 65 (position detection step). Thereafter, the opening/closing mechanism 67 is closed. The semiconductor wafer W is conveyed from the vacuum atmosphere preparation chamber 60 to the reduced pressure atmosphere conveyance chamber 70 by the conveyance mechanism 72 of the reduced pressure atmosphere conveyance chamber 70. Thereafter, the opening/closing mechanism 67 is closed.

Thereafter, the vacuum pump 83 is operated so that the inner pressure of the reduced pressure atmosphere conveyance chamber 70 becomes nearly the same as the inner pressure of the exposure treatment chamber 90 that has been set at a predetermined reduced pressure (the inner pressures of the reduced pressure conveying chamber 70 and the exposure treatment chamber 90 may be set so that the inner pressure of the reduced pressure atmosphere conveyance chamber 70 is slightly lower than the exposure treatment chamber 90 to prevent particles from entering the exposure treatment chamber 90).

Thereafter, the opening/closing mechanism 92 is opened. The conveyance mechanism 72 of the reduced pressure atmosphere conveyance chamber 70 adjusts the entering angle of the semiconductor wafer W into the exposure treatment chamber 90 according to the position detection data of the CCD cameras 65 and conveys the semiconductor wafer W to the exposure treatment chamber 90. Before or after the semiconductor wafer W is conveyed to the exposure treatment chamber 90, the stage 91 of the exposure treatment chamber 90 is moved to an expected transfer position for the semiconductor wafer W with the conveyance mechanism 72 (referred to as the first alignment in the exposure treatment section 5). After the conveyance mechanism 72 has left from the exposure treatment chamber 90, the opening/closing mechanism 92 is closed.

In the exposure treatment chamber 90, the mark detection mechanism 105 detects the alignment mark on the semiconductor wafer W chucked by the static chuck mechanism 110 on the stage 91. The stage 91 is moved in the X and Y directions according to the detection data. Finally, the semiconductor wafer W is aligned (referred to as the second alignment in the exposure treatment section 5). After the semiconductor wafer W has been aligned, an acceleration voltage, for example a predetermined voltage in the range from 1 kV to 60 kV, preferably a predetermined voltage in the range from 1 kV to 10 kV, more preferably 5 kV, is applied from the column 100 to the resist film formed on the semiconductor wafer W so that a predetermined pattern is formed on the semiconductor wafer W in the exposure treatment. It is preferred that an acceleration voltage that causes the electron beam to work on the resist film formed on the semiconductor wafer W be set. It is important to prevent electrons of the electron beam emitted to silicon (Si) as a base material of the semiconductor wafer W from scattering although the electron beam is affected by the inner pressure of the exposure treatment chamber 90.

After the exposure treatment has been performed, the stage 91 is moved to a transfer position for the semiconductor wafer W with the conveyance mechanism 72. After the static chuck mechanism 110 releases the semiconductor wafer W, the semiconductor wafer W is unloaded from the exposure treatment chamber 90 by the conveyance mechanism 72. Thereafter, the semiconductor wafer W is loaded into the vacuum atmosphere preparation chamber 60 by the conveyance mechanism 72. The conveyance mechanism 20 unloads the semiconductor wafer W from the vacuum atmosphere preparation chamber 60. The conveyance mechanism 20 conveys the unloaded semiconductor wafer W to the temperature adjustment plate 27 of the heat treatment section 22.

The semiconductor wafer W is placed on the temperature adjustment plate 27 or held by the conveyance mechanism 20 in standby state until a predetermined period (this time period is the same for each of semiconductor wafers W) has elapsed according to information calculated by the control mechanism 166 in consideration of the reduced pressure and time under the reduced pressure atmosphere based on end time of the exposure treatment. Thereafter, the semiconductor wafer W is placed on the heat plate 26. The heat treatment is performed for the semiconductor wafer W on the heat plate 26. Since the heat start time needs to be constant for each of a plurality of semiconductor wafers W, when the semiconductor wafer W is placed in standby state on the temperature adjustment plate 27, conveyance time for the semiconductor wafer W from the temperature adjustment plate 27 to the heat plate 26 needs to be managed. When the semiconductor wafer W is kept in standby state in the conveyance mechanism 20, conveyance time for the semiconductor wafer W from the conveyance mechanism 20 to the temperature adjustment plate 27 and conveyance time for the semiconductor wafer W from the temperature adjustment plate 27 to the heat plate 26 need to be managed.

The semiconductor wafer W that has been heated by the heat plate 26 at a predetermined temperature for a predetermined time period is transferred to the temperature adjustment plate 27. After the semiconductor wafer W is transferred from the temperature adjustment plate 27 to the conveyance mechanism 20, the semiconductor wafer W is unloaded from the heat treatment section 22 by the conveyance mechanism 20.

After or immediately after the alignment mechanism 21 temporarily aligns the semiconductor wafer W, the conveyance mechanism 20 directly conveys the semiconductor wafer W to the reception section 11 of the resist treatment device 2. When the conveyance mechanism 20 conveys the semiconductor wafer W to the reception section 11, the control mechanism 180 or/and the control mechanism 166 need to have asked the control mechanism 184 whether the reception section 11 has a semiconductor wafer W. Only when the conveyance mechanism 20 has checked that the reception section 11 does not have a semiconductor wafer W, the conveyance mechanism 20 conveys the semiconductor wafer W to the reception section 11 of the resist treatment device 2. Before or after the conveyance mechanism 20 conveys the semiconductor wafer W to the reception section 11, the control mechanism 180 or/and the control mechanism 166 transmit substrate information of the semiconductor wafer W and information about end time and so forth of the heat treatment of the heat plate 26 to the control mechanism 184.

While the control mechanism 184 is managing times according to the information, the control mechanism 184 conveys the semiconductor wafer W to the developing device (developer: DEV). The developing device performs a development treatment for the semiconductor wafer W. Thereafter, the sequence of treatment operations is completed.

The system composed of a treatment section for example an exposure treatment chamber that treats for example a substrate under treatment for example under a reduced pressure atmosphere; a reduced pressure atmosphere conveyance chamber that has a conveyance mechanism that conveys the substrate under treatment to the exposure treatment chamber under a reduced pressure atmosphere; a vacuum atmosphere preparation chamber that can freely unload the substrate under treatment to the reduced pressure atmosphere conveyance chamber; and a linear air aligner section that has a conveyance mechanism that can freely convey the substrate under treatment under air atmosphere to the vacuum atmosphere preparation chamber is particularly effective when the footprint of the exposure treatment chamber is sufficiently larger than the footprint of the reduced pressure atmosphere conveyance chamber or the vacuum atmosphere preparation chamber or the footprint of the reduced pressure atmosphere conveyance chamber is close to the footprint of the vacuum atmosphere preparation chamber. When the reduced pressure atmosphere conveyance chamber or the vacuum atmosphere preparation chamber is disposed in parallel with and adjacent to the linear air aligner section (the reduced pressure atmosphere conveyance chamber is disposed at the center of the air aligner section and the vacuum atmosphere preparation chamber is disposed at one end of the air aligner section), the footprint of the system can be decreased in comparison with the system of the related art. As a result, the size of the whole system can be decreased. When the area of the footprint of the exposure treatment chamber is larger than the area of the footprint of the reduced pressure atmosphere conveyance chamber and the vacuum atmosphere preparation chamber, the area of the footprint of the whole system can be decreased in comparison with that of the related art.

In the foregoing system, since one control mechanism totally manages the heat treatment section that performs the heat treatment for a substrate under treatment for which the exposure treatment has been performed by the exposure treatment chamber in consideration of treatment mistakes due to excessive treatment time or atmospheric conditions, the yield of the treatment for substrates under treatment can be improved. In addition, since a plurality of substrates under treatment can be prevented from differing in the treatment. As a result, the yield of substrates under treatment can be improved.

In addition, since temperature information of the heat treatment or/and information about end time of the heat treatment are transmitted to a device that applies resist solution onto a substrate under treatment, a resist treatment device as another device can perform a treatment with parameters according to a plurality of pieces of information. As a result, the yield of substrates under treatment can be improved.

When a substrate under treatment is aligned for the exposure treatment, in consideration of the alignment accuracies of other devices, the position accuracy in the exposure treatment can be improved. In addition, the yield of the exposure treatment can be improved. Instead, the throughput of the alignment can be improved.

Next, another embodiment of the present invention will be described. Unless otherwise specified, in this embodiment, similar reference numerals to those of the foregoing embodiment are denoted by similar reference numerals and their description will be omitted.

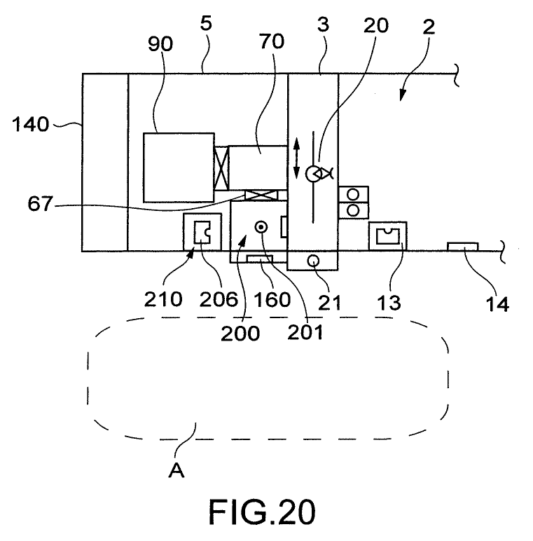

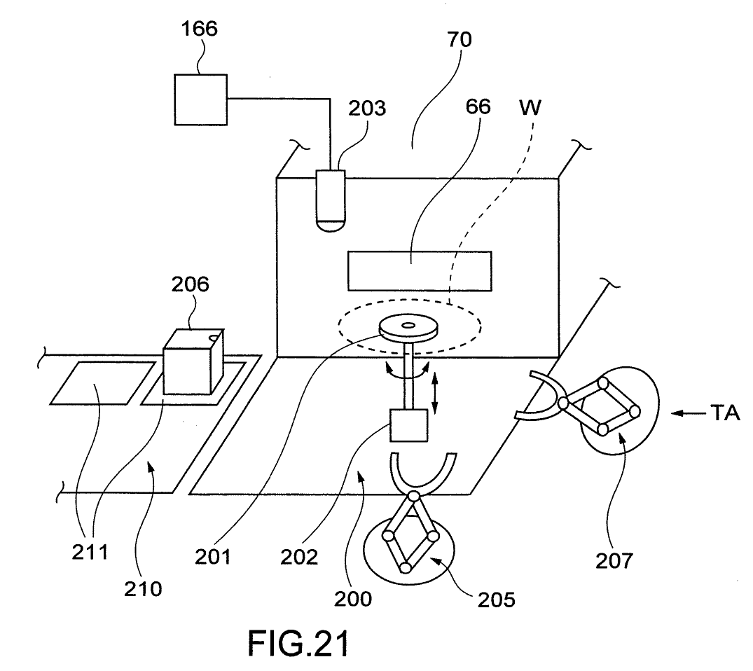

As shown in FIG. 20 and FIG. 21, in an exposure treatment section 5, a substrate loading/unloading section 200 is disposed. A semiconductor wafer W is loaded and unloaded into and from the substrate loading/unloading section 200 by a conveyance mechanism 20 of an air aligner section 3. The substrate loading/unloading section 200 is disposed under the atmosphere of the exposure treatment section 5 or under the atmosphere of the air aligner section 3. The substrate loading/unloading section 200 has a rotation member, for example, a rotation table 201, that vacuum chucks a semiconductor wafer W conveyed by the conveyance mechanism 20 (from the direction TA) of the air aligner section 3. The rotation table 201 can be freely raised and lowered by a raising/lowering mechanism for example an air cylinder 202, to transfer the semiconductor wafer W to and from the conveyance mechanism 20.

Disposed above the rotation table 201 is a detection means, for example, a reflection type optical sensor 203 (for example, a CCD camera) that optically or visually detects the periphery of the semiconductor wafer W held on the rotation table 201. While the rotation table 201 is being rotated, the peripheral portion, for example a notch portion, of the semiconductor wafer W is detected by the optical sensor 203. The semiconductor wafer W is aligned with the detected notch (referred to as the first alignment in the exposure treatment section 5).

In addition, the substrate loading/unloading section 200 has a first conveyance mechanism 205 that conveys a semiconductor wafer W on the rotation table 201 to a reduced pressure atmosphere conveyance chamber and a second conveyance mechanism 207 that can freely load and unload the semiconductor wafer W into and from a container for example a cassette 206 that can contain a plurality of semiconductor wafers W. The cassette 206 is disposed opposite to the second conveyance mechanism 207. The cassette 206 is placed on a cassette table 210. A plurality of cassettes 206 can be placed on the cassette table 210. The cassette table 210 has a plurality of cassette raising/lowering mechanisms 211 that can freely raise and lower cassettes 206. The second conveyance mechanism 207 can transfer a semiconductor wafer W to and from the cassette raising/lowering mechanisms 211.

The cassette 206 can be freely conveyed from the cassette table 210 to the outside of the apparatus or vice versa through an opening/closing mechanism. Since the exposure treatment section 5 has the cassette table 210 and the cassette 206 can be conveyed from the outside of the apparatus to the cassette table 210 or vice versa, the exposure treatment can be performed for a test semiconductor wafer W in the exposure treatment section 5. In addition, even if a semiconductor wafer W is improperly treated in the exposure treatment section 5, the semiconductor wafer W can be removed from the cassette table 210. Thus, the operation efficiency is relatively improved. In addition, the worker can work for both the resist treatment device 2 and the exposure treatment section 5 in a common space A. Thus, the work efficiency is improved.

Thus, operation panels 160 and 14 of these devices are disposed adjacent to the work space A. In addition, the cassette tables 210 and 13 are disposed adjacent the work space A. In addition, when the semiconductor wafer W can be removed from the work space A adjacent to the alignment mechanism 21 of the air aligner section 3, the work efficiency of the worker is improved. In addition, the footprint of the whole apparatus in the clean room can be decreased.

As an operation of which a semiconductor wafer W is removed from the cassette 206 on the cassette table 210 and a treatment is performed for the semiconductor wafer W only in the exposure treatment section 5, a semiconductor wafer W under treatment is removed from the cassette 206 by the second conveyance mechanism 207 and placed on the rotation table 201. While the rotation table 201 is being rotated, the peripheral portion for example a notch portion of the semiconductor wafer W is detected by the optical sensor 203. With the detected notch portion, the semiconductor wafer W is aligned (referred to as the first alignment of the exposure treatment section 5). Thereafter, the first conveyance mechanism 205 conveys the semiconductor wafer W to the reduced pressure atmosphere conveyance chamber 70. The exposure treatment chamber 90 performs the exposure treatment for the semiconductor wafer W. In the reverse procedure, the second conveyance mechanism 207 loads the semiconductor wafer W into the cassette 206. Of course, the position information of the optical sensor 203 is considered when the semiconductor wafer W is transferred between the reduced pressure atmosphere conveyance chamber 70 and the exposure treatment chamber 90. When the semiconductor wafer W is conveyed to the reduced pressure atmosphere conveyance chamber 70, the first conveyance mechanism 205 is used. Instead, the conveyance mechanism 72 of the reduced pressure atmosphere conveyance chamber may be used.

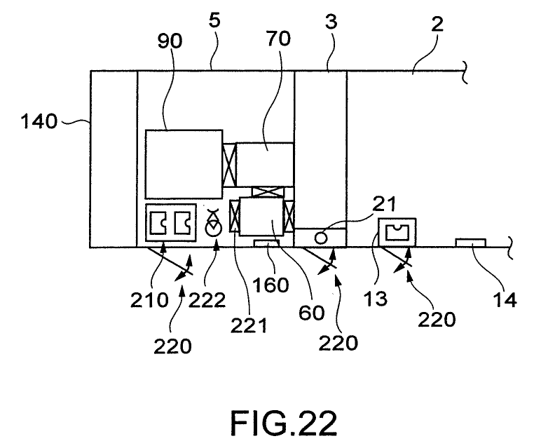

As another example of the structure of which the cassette 206 is placed, as shown in FIG. 22, an opening/closing mechanism 221 is disposed adjacent to the vacuum atmosphere preparation chamber 60 opposite to the air aligner section 3. Disposed outside the opening/closing mechanism 221 is an conveyance mechanism 222. Disposed outside the conveyance mechanism 222 is the cassette table 210 on which a plurality of cassettes 206 can be placed. In this structure, the foregoing function can be added. Thus, the same effect as the foregoing structure can be accomplished. In FIG. 22, reference numeral represents a door mechanism through which the worker can access a cassette or a semiconductor wafer W from the work space.

Next, another embodiment of the present invention will be described. In this embodiment, similar sections to those of the foregoing embodiments are denoted by similar reference numerals and their description will be omitted.

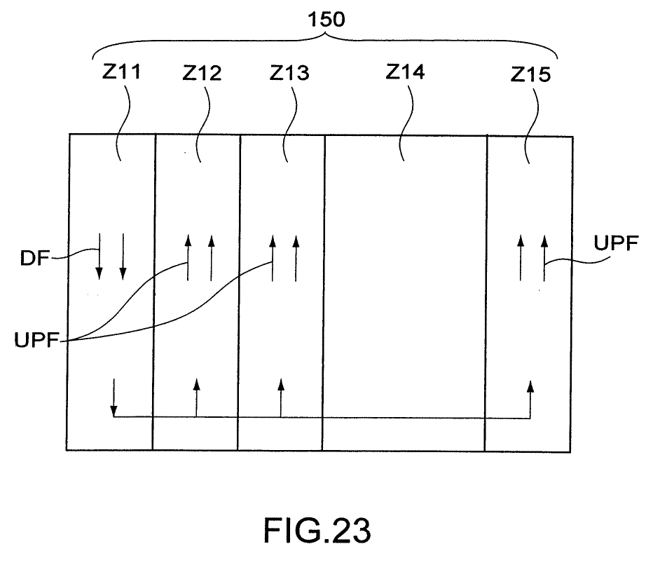

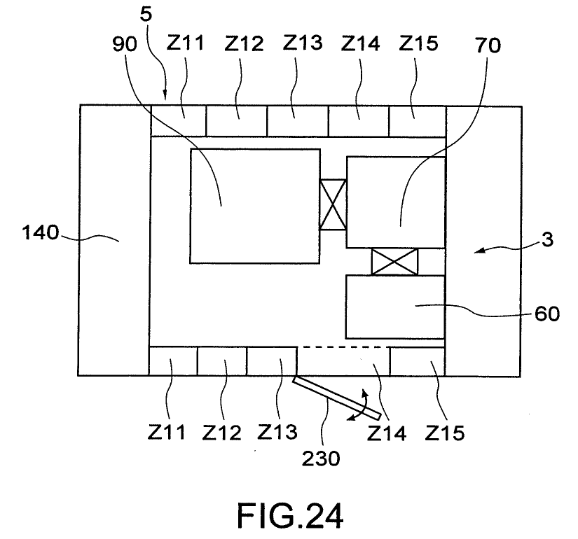

As shown in FIG. 23 and FIG. 24, air flow paths 150 of an exposure treatment section 5 are divided into a plurality of zones Z11, Z12, Z13, Z14, and Z15. In a flow path of the zone Z11, clean air flows downward as a down flow DF. In flow paths of the zones Z12, Z13, and Z15, clean air flows upward as up flows UPF. The zone Z14 has a predetermined width for example a space portion larger than the width of the other zones Z11, Z12, Z13, and Z15. The inner atmosphere of the zone Z14 is the same as the inner atmosphere of the exposure treatment chamber 90.

In addition, a door mechanism 230 is disposed in the zone Z14. The worker can freely open and close the door mechanism 230 from the work area. Since the door mechanism 230 is disposed and the inner atmosphere of at least one of a plurality of air flow paths 150 is the same as the inner atmosphere of the exposure treatment chamber 90, a maintenance space for the worker can be provided. This space is preferably disposed adjacent to the cassette area. In this example, the worker can easily perform maintenance work for at least the exposure treatment chamber 90, the reduced pressure atmosphere conveyance chamber 70, and the vacuum atmosphere preparation chamber 60 from a maintenance area of the zone 14. As a result, the work efficiency of maintenance work can be improved.

When the space of the zone Z14 is disposed adjacent to the cassette area, the space for the door mechanism 230 and the zone Z14 may be horizontally divided, namely partitioned so that the upper portion is used for the cassette table area and the lower portion is used for the space for which the worker can work for the exposure treatment section 5 through a lower door mechanism.

Next, another embodiment of the present invention will be described. In this embodiment, similar sections to those of the foregoing embodiments are denoted by similar reference numerals and their description will be omitted.

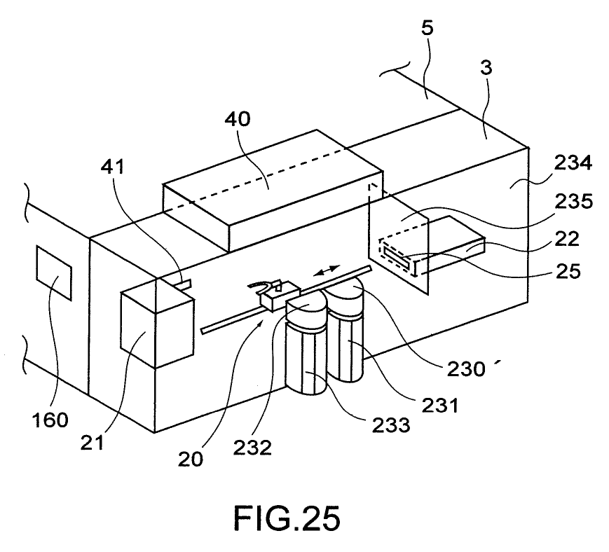

FIG. 25 shows an example of an air aligner section 3 that is not connected to a resist treatment device 2, not inline-connected thereto. In this case, an unloader mechanism 231 and a loader mechanism 232 can be freely connected to a wall portion 234 of the air aligner section 3. The unloader mechanism 231 contains a container for example a cassette that contains a plurality of substrates that have been treated. The unloader mechanism 231 can shield the inner atmosphere of the cassette against the other atmosphere, have a cassette conveyance member 230′ that can contain the cassette, and freely raise and lower it without moving the cassette conveyance member 230′. The loader mechanism 233 contains a container for example a cassette that contains a plurality of substrates that have not been treated. The loader mechanism 233 can shield the inner atmosphere of the cassette against the other atmosphere, have a cassette conveyance member 230′ that can contain the cassette, and freely raise and lower it without moving the cassette conveyance member 230′.

The conveyance mechanism 20 can freely unload a substrate that has not been treated from the cassette contained in the cassette conveyance member 232 of the loader mechanism 233. In addition, the conveyance mechanism 20 can freely load a substrate that has been treated into the cassette of the cassette conveyance member 230′. Thus, in this standalone type system structure, it is preferred that the cassette conveyed from the outside of the apparatus be placed adjacent to the air aligner section 3 and opposite to the exposure treatment section (in the longitudinal direction of the linear air aligner section 3). As a result, the footprint of the whole apparatus in the clean room can be decreased. Instead, the footprint of the width of the access space for the worker can be decreased.

When a work space for a worker that carries a cassette conveyance member or a robot such as an AGV is disposed adjacent to the cassette area and the operation panel 160 is disposed adjacent to the wall portion 234, namely adjacent to the cassette area, the work efficiency of the worker can be improved. Reference numeral 235 represents a wall portion as an atmosphere shield mechanism that shields the atmosphere of the conveyance mechanism 20 from the atmosphere of the heat treatment section 22. In addition, since the loader mechanism 233 is disposed adjacent to the alignment mechanism 21 of the air aligner section 3 and the unloader mechanism 231 is disposed adjacent to the heat treatment section 22, conveyance time for which the conveyance mechanism 20 conveys a substrate that has not been treated from the loader mechanism 233 to the alignment mechanism 21 and conveyance time for which the conveyance mechanism 20 conveys a substrate that has been treated from the loader mechanism 233 to the alignment mechanism 21 can be effectively shortened. Thus, the throughput of the conveyance and so forth can be improved.

Next, another embodiment of the present invention will be described. In this embodiment, similar sections to those of the foregoing embodiments are denoted by similar reference numerals and their description will be omitted.

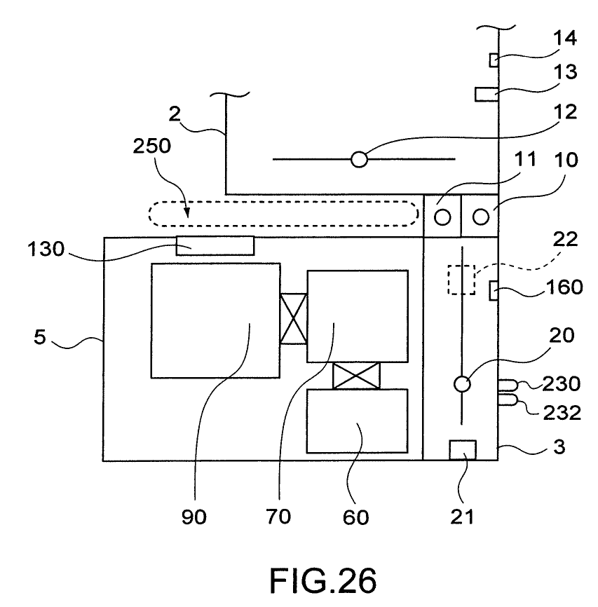

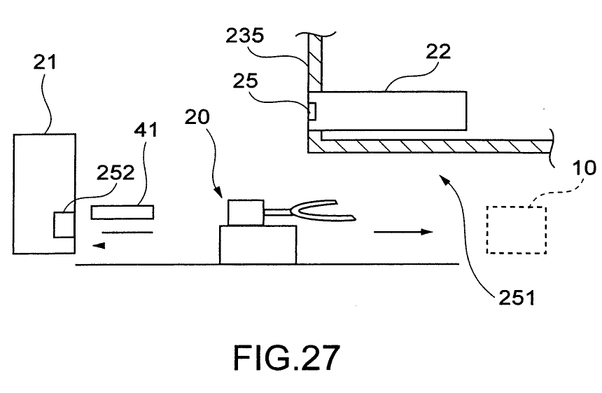

FIG. 26 and FIG. 27 shows the structure of an exposure device and a resist treatment device that are inline-connected. In this example, the exposure device and the resist treatment device are inline-connected with an unloader mechanism 231 and a loader mechanism 233, namely a cassette conveyance member 232 and a cassette conveyance member 230′.

A resist treatment device 2 and an air aligner section 3 can transfer a semiconductor wafer W between a reception section 11 and a supply section 10 disposed at one end opposite to an alignment mechanism 21 disposed in the longitudinal direction of the air aligner section 3. In addition, a space portion for example a maintenance space portion 250 for which a worker performs maintenance work is disposed between the resist treatment device 2 and the exposure treatment section 5. Disposed adjacent to the maintenance space portion 250 of the exposure treatment chamber 90 of the exposure treatment section 5 is an amplifier section 130. As a result, maintenance work for the amplifier section 130 can be effectively performed in the maintenance space portion 250.

Disposed below the heat treatment section 22 is a conveyance space portion 251 in which a conveyance mechanism 20 can be freely moved. The conveyance mechanism 20 moves in the conveyance space portion 251 so that a semiconductor wafer W can be transferred between the reception section 11 and the supply section 10.

The height of a loading/unloading opening 25 of the heat treatment section 22 is larger than the height of a loading/unloading opening 252 for a semiconductor wafer W of the alignment mechanism 21 or the height of a loading/unloading opening 41 of a vacuum atmosphere preparation chamber 60. Disposed in the longitudinal direction of the air aligner section 3 are the unloader mechanism 231 and the loader mechanism 233. Disposed along the air aligner section 3 is an operation panel 14 and so forth of the resist treatment device 2. It is preferred that a work's access space be disposed adjacent to these devices. Likewise, it is preferred that an operation panel 160 of the exposure apparatus be disposed adjacent to these devise.

When the worker can access a semiconductor wafer W placed on the reception section 11 and the supply section 10 from the work area through a door mechanism (not shown), the work efficiency is further improved. In addition, the width of the space of the work area can be decreased and the footprint of the apparatus can be decreased. In addition, since the maintenance space portion 250 is disposed between the resist treatment device 2 and the exposure treatment section 5, a common maintenance space can be formed for two different devices. Thus, the footprint of the maintenance space can be decreased. In addition, since the worker can access difference devices from the common space, maintenance time can be shortened.

Embodiments of the present invention were described. However, the present invention is not limited to these embodiments. Instead, various modifications and changes of the embodiments may be made according to the spirit of the present invention. In the foregoing embodiments, semiconductor wafers as substrates under treatment were described. Instead, LCDs may be used as substrates under treatment. In addition, according to the foregoing embodiments, the air aligner section is integrated with the exposure treatment section as a system or with the resist treatment device and the exposure treatment section as a system. Instead, the air aligner section may be integrated with other devices as a system. Instead, the air aligner section may be disposed between other first and second devices as a system.

(Second Embodiment)

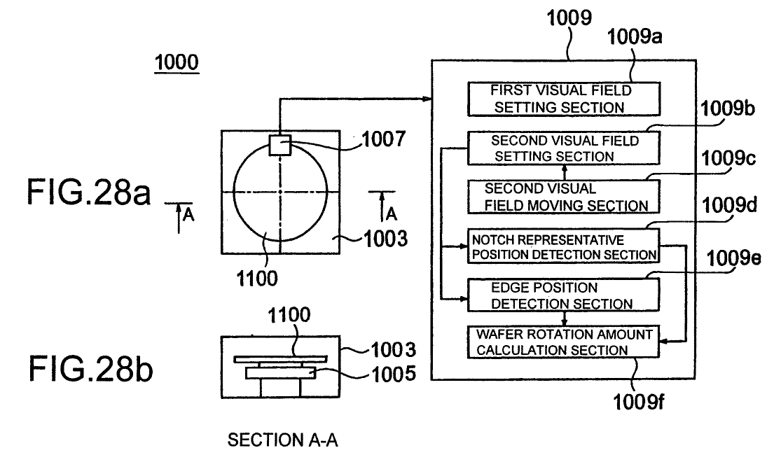

FIG. 28A and FIG. 28B show the structure of a wafer rotation position detection apparatus according to a second embodiment of the present invention. A wafer rotation position detection apparatus 1001 according to this embodiment has a chamber 1003, a stage 1005 that is disposed in the chamber 1003 and on which a wafer 1100 is placed, a photographing device 1007 that is composed of for example a CCD camera that detects the rotation position of the wafer, and an image process device 1009 that processes image data captured by the photographing device 1007. The image process device 1009 has a first visual field setting section 1009a, a second visual field setting section 1009b, a second visual field moving section 1009c, a notch representative position detection section 1009d, an edge position detection section 1009e, and a wafer rotation amount calculation section 1009f.

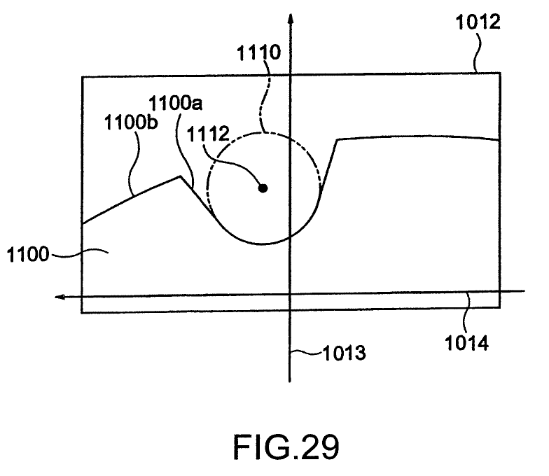

Next, with reference to FIG. 29 to FIG. 31, the operation of the wafer rotation position detection apparatus 1001 according to this embodiment will be described.

Firstly, the wafer 1100 is placed on the stage 1005 so that a notch portion 1100a of the wafer 1100 and a contour portion 1100b enter the visual field of the photographing device 1007. As a result, a first visual field 1012 as a fixed visual field is set in the visual field of the photographing device 1007 according to image data captured by the photographing device 1007 (see FIG. 29). A vertical reference line 1013 and a horizontal reference line 1014 are set in the first visual field 1012. These vertical reference line 1013 and horizontal reference line 1014 may be set at the fringe of the first visual field 1012.

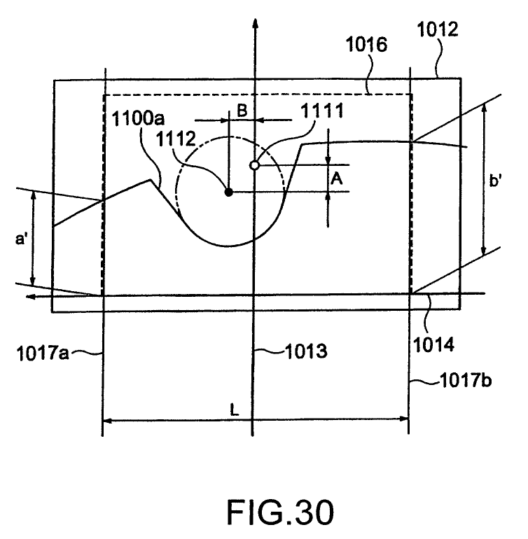

Next, as shown in FIG. 30, a second visual field 1016 that is narrower than the first visual field is set in the first visual field 1012 by the second visual field setting section 1009b. The second visual field 1016 is a movable visual field. The second visual field 1016 can be moved by the second visual field moving section 1009c in the horizontal direction (in the left and right directions shown in FIG. 30). The initial position of the second visual field 1016 is set so that for example a reference notch representative position 1111 is placed at the center of the second visual field 1016. The reference notch representative position 1111 is pre-set with a jig wafer (not shown) that has a hole at a position corresponding to the reference notch representative position 1111.

The notch representative position detection section 1009d detects a notch representative position 1112 with contour information of the wafer 1100 by a known pattern matching method. According to this embodiment, the notch representative position detection section 1009d detects coordinates of at least three different positions on an arc of the notch portion 1100a, calculates a center 1112 of a virtual circle 1110 that contacts the arc according to the coordinates of three positions, and designates the calculated center 1112 as the notch representative position (see FIG. 30). The notch representative position detection section 1009d calculates a vertical distance A and a horizontal distance B between the detected notch representative position 1112 and the pre-set reference notch representative position 1111.

Two parallel edge position detection lines 1017a and 1017b that are in parallel with the vertical reference line 1013 are set in the second visual field 1016. The edge position detection lines 1017a and 1017b are fixed in the second visual field 1016. The edge position detection lines 1017a and 1017b are spaced apart by a distance L. Thus, the edge position detection lines 1017a and 1017b are moved as the second visual field 1016 is moved.

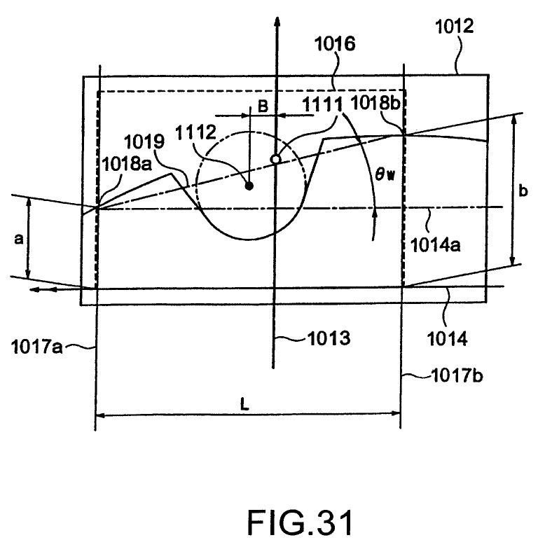

Next, the second visual field 1016 is moved by the second visual field moving section 1009c for the horizontal distance B so that the detected notch representative position 1112 is placed at the horizontal center position of the second visual field 1016 (see FIG. 31). Thereafter, the edge position detection section 1009e detects intersections 1018a and 1018b of the edge position detection lines 1017a and 1017b placed in the second visual field 1016 and the contour portion 1100b of the wafer 1100 and obtains distances a and b from the intersections 1018a and 1018b to the horizontal reference line 1014. As is clear from FIG. 31, an angle θw made of a straight line 1014a that passes through the intersection 1018a and that is in parallel with the horizontal reference line 1014 and a straight line 1019 that passes through the intersections 1018a and 1018b is a wafer rotation amount for which the inclination of the wafer 1100 is removed (leveled). Thus, the wafer rotation amount calculation section 1009f obtains the wafer rotation amount θw with these distances a and b and the distance L between the edge position detection lines 1017a and 1017b according to the following formula.
θw=(b−a)/L

In this embodiment, the counterclockwise direction of the rotation amount θw is defined as the positive direction.

When the second visual field 1016 is not moved and distances a′ and b′ from intersections of the edge position detection lines 1017a and the 1017b and the contour portion 1100b of the wafer 1100 to the horizontal reference line 1014 are substituted for the distances a and b of the foregoing formula, the obtained rotation amount contains the shift amount B and the wafer rotation amount θw as shown in FIG. 30.

Thus, according to this embodiment, with the edge position detection lines 1017a and 1017b, which are fixed in the second visual field 1016 and are horizontally moved as the second visual field 1016 is horizontally moved, the influence of the shift amount B can be removed.

Next, the detection error of the wafer rotation amount is considered. It is assumed that image information of a first visual field having a size of 8 mm×6 mm is obtained by a CCD camera 7 having a resolution of 800 pixels×600 pixels, one pixel corresponds to 10 μm. When the obtained image information is processed, a resolution of 1/10 can be obtained. In other words, a resolution of 1 μm (= 1/10 pixels) can be accomplished.

It is assumed that the size of the second visual field 1016 is 6 mm×4 mm and the distance L between the two edge position detection lines 1017a and 1017b is 6 mm. Since the read resolution of intersections of the edge position detection lines 1017a and 1017b and the contour portion 1100b of the wafer 1100 is 1 μm. Thus, the error of the rotation amount θw is 1 μm/6 mm=⅙ milli-radian≠0.01 degrees.

As was described above, according to this embodiment, with one camera, the rotation position of a wafer can be detected.

(Third Embodiment)

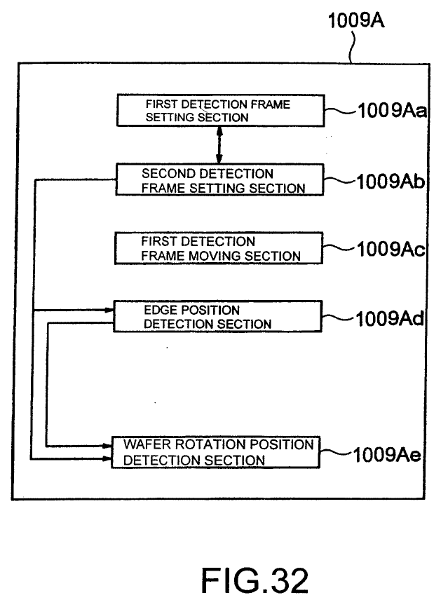

Next, with reference to FIG. 32 to FIG. 34, a wafer rotation position detection apparatus according to a third embodiment of the present invention will be described. The wafer rotation position detection apparatus according to this embodiment has a structure of which the image process device 1009 of the wafer rotation position detection apparatus according to the second embodiment shown in FIG. 2 is replaced with an image process device 1009A shown in FIG. 32. FIG. 32 is a block diagram showing the structure of the image process device 1009A according to the third embodiment. The image process device 1009A has a first detection frame setting section 1009Aa, a second detection frame setting section 1009Ab, a first detection frame moving section 1009Ac, an edge position detection section 1009Ad, and a wafer rotation amount calculation section 1009Ae.

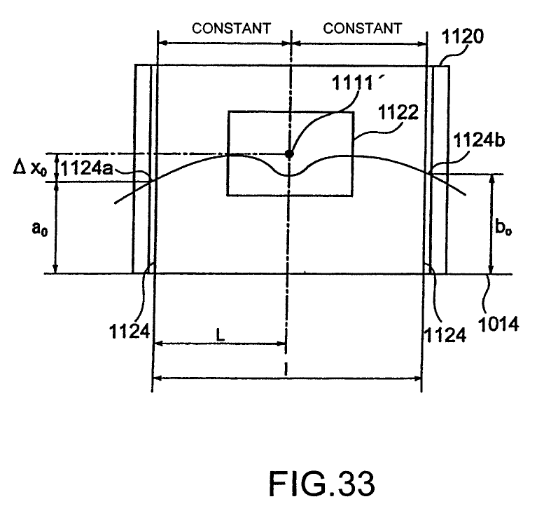

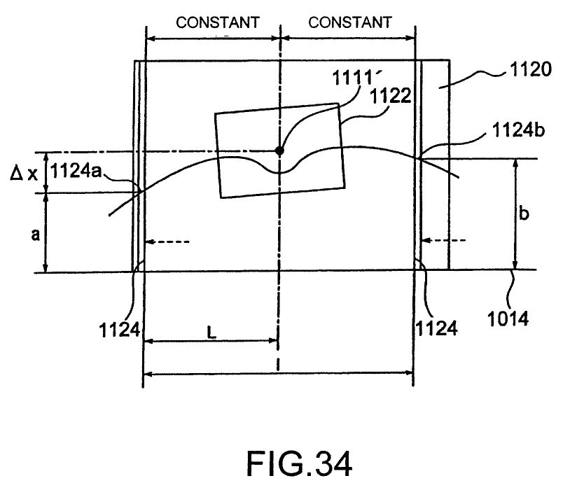

Next, with reference to FIG. 33 and FIG. 34, the operation of the wafer rotation position detection apparatus according to this embodiment will be described. The first detection frame setting section 1009Aa sets a first detection frame 1122 that is a pattern matching detection frame with which a notch shape of a wafer is recognized in a visual field 1120 of a photographing device 7 that is composed of for example a CCD camera. The second detection frame setting section 1009Ab sets a second detection frame 1124 with which an edge (contour) of the wafer is detected in the visual field 1120 of the photographing device 7. The second detection frame 1124 is kept apart from one coordinate element of reference position coordinates 1111′ of the first detection frame 1122 (in the horizontal direction (left and right directions shown in FIG. 33). When the first detection frame 1122 is moved by the first detection frame moving section 1009Ac, the second detection frames 1124 is horizontally slid as the first detection frame 1122 is moved. In this embodiment, two second detection frames 1124 are placed on the left and right. The distance between one (left second detection frame 1124 shown in FIG. 33) of the second detection frames 1124 and the reference position coordinates 1111′ of the first detection frame 1122 is L. The second detection frames 1124 have an inclination that has been initially set. When the second detection frames 1124 are moved as the first detection frame 1122 is moved, the distance L between the left second detection frame 1124 and the reference position coordinates 1111′ is kept constant. A horizontal distance 1 between the second detection frames 1124 is constant. In this embodiment, the reference position coordinates 1111′ of the first detection frame 1122 are set at the center of the first detection frame 1122. The lower ends of the second detection frames 1124 contact the horizontal reference line 1014.

When the wafer rotation position of a first wafer in the same lot is detected, the wafer or a jig wafer is placed on a stage 1005 in a chamber 1003 so that the notch portion of the wafer or the jig wafer enters the visual field of the photographing device 7, the inclination of the wafer is nearly zero, and the center of the first detection frame 1122 nearly matches the center of the groove of the notch portion (see FIG. 33). The edge position detection section 1009Ad detects the edge of the wafer with the second detection frames 1124 that have been set by the second detection frame setting section 1009Ab, namely intersections 1124a and 1124b of the contour of the wafer and the second detection frames 1124. As a result, distances a0 and b0 between the intersections 1124a and 1124b and the horizontal reference line 1014 are obtained. With the obtained distances a0 and b0, the wafer rotation amount calculation section 1009Ae calculates a wafer rotation amount θ0 in the initial state according to the following formula.
θ0=(a0−b0)/1

Next, the wafer is placed on the stage 1005 to detect the rotation amount. The first detection frame moving section 1009Ac detects and recognizes the notch portion of the wafer by for example the pattern match method. At this point, the reference position coordinates 1111 of the first detection frame are moved according to the notch portion. FIG. 34 shows the first detection frame 1122 in the state that the first detection frame moving section 1009Ac has recognized the notch portion of the wafer. At this point, the second detection frames 1124 are moved as the first detection frame 1122 is moved. However, the second detection frames 1124 are moved with the inclination that has been initially set (see FIG. 34).

Next, the edge position detection section 1009Ad detects the intersections 1124a and 1124b of the contour of the wafer and the second detection frames 1124. As a result, distances a and b from the intersections 1124a and 1124b to the horizontal reference line 1014 are obtained (see FIG. 34). With the obtained distances a and b and the initial wafer rotation amount θ0, the wafer rotation amount calculation section 1009Ae calculates the current rotation amount θ of the wafer according to the following formula.
θ=(a−b)/L−θ0.

In this manner, only inclination of wafer misalignment information can be obtained.

(Modification)

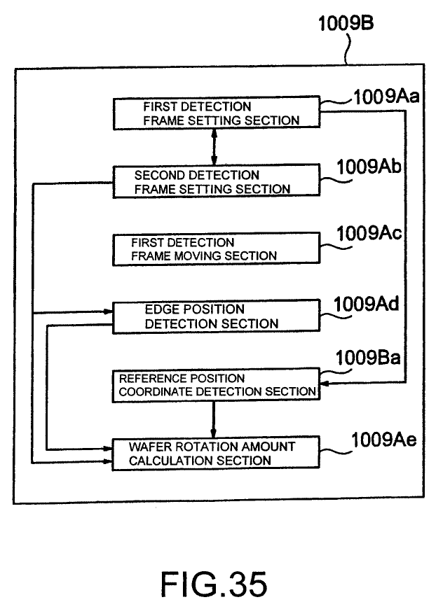

According to the third embodiment, with two second detection frames 1124, the inclination of a semiconductor wafer W is obtained. Instead, with one second detection frame 1124, the inclination of a semiconductor wafer W can be obtained. This structure will be described as a modification of the third embodiment. The wafer rotation position detection apparatus of this modification has a structure of which only left second detection frame 1124 of two second detection frames 1124 shown in FIG. 33 is disposed and the image process device 9 of the wafer rotation position detection apparatus according to the second embodiment shown in FIG. 32 is replaced with an image process device 1009B shown in FIG. 35. The image process device 1009B has the same structure as the image process device 1009A except that a reference position coordinate detection section 1009Ba is newly disposed.

In this modification, the initial inclination θ0 of a wafer is obtained according to the following formula.
θ0=Δx0/L

where Δx0 represents the distance between the reference position coordinates 1111′ of the first detection frame 1122 and the left second detection frame 1124 (see FIG. 33). The real rotation amount θ of the wafer can be obtained according to the following formula.
θ=Δx/L−θ0

where Δx represents the distance between the reference position coordinates 1111 of the first detection frame 1122 and the left second detection frame 1124 (see FIG. 34).

Thus, this modification provides the same effect as the third embodiment of the present invention.

(Fourth Embodiment)

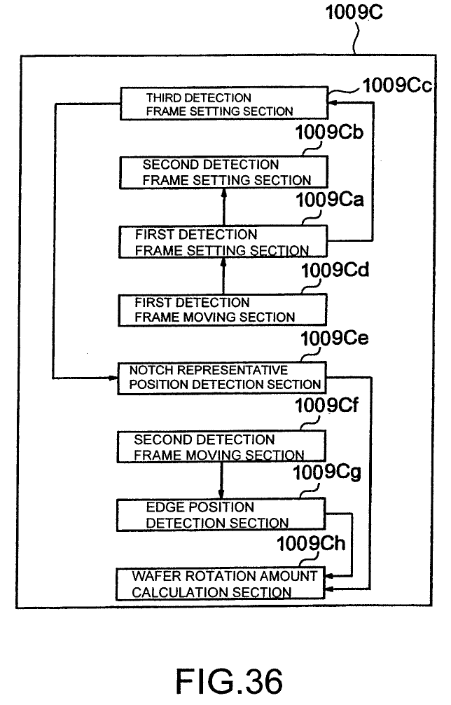

Next, with reference to FIG. 36 to FIG. 38, a wafer rotation position detection apparatus according to a fourth embodiment will be described. The wafer rotation position detection apparatus according to this embodiment has a structure of which the image process device 1009 of the wafer rotation position detection apparatus of the second embodiment shown in FIG. 28 is replaced with an image process device 1009C shown in FIG. 36. FIG. 36 is a block diagram showing the structure of the image process device 1009C. The image process device 1009C has a first detection frame setting section 1009Ca, a second detection frame setting section 1009Cb, a third detection frame setting section 1009Cc, a first detection frame moving section 1009Cd, a notch representative position detection section 1009Ce, a second detection frame moving section 1009Cf, an edge position detection section 1009Cg, and a wafer rotation amount calculation section 1009Ch.

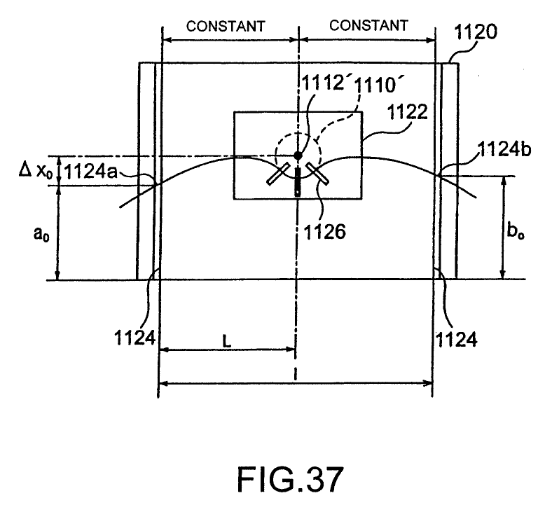

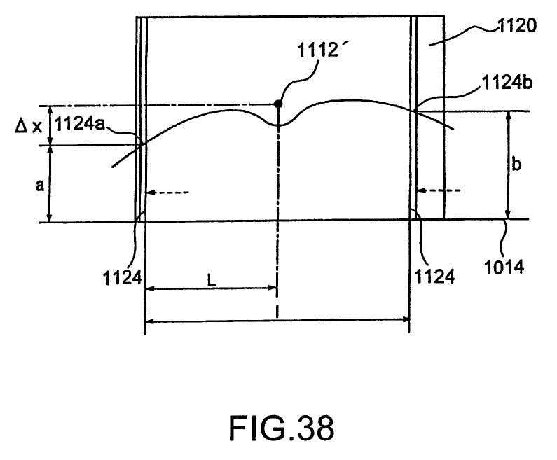

Next, with reference to FIG. 37 and FIG. 38, the operation of the wafer rotation position detection apparatus according to this embodiment will be described.

When a wafer is placed on a stage 1005, the first detection frame setting section 1009Ca sets a first detection frame 1122 as a pattern matching detection frame, with which a notch shape of the wafer is recognized, in a visual field 1120 of a photographing device 1007 composed of a CCD camera. The second detection frame setting section 1009Cb sets second detection frames 1124, with which an edge of the wafer (contour) is detected, in the visual field 1120 of the photographing device 1007. The third detection frame setting section 1009Cc sets three third detection frames 1126 in the first detection frame 1122. According to this embodiment, the number of third detection frames 1126 is three. The three detection frames 1126 are disposed on a concentric circle of a reference position 1112 of the first detection frame 1122 so that the distance between each of the third detection frames 1126 and the reference position 1112 is constant. The second detection frames 1124 are moved as the first detection area frame 1122 is moved so that the distance from each of the second detection frames 1124 to the coordinates of a notch representative position obtained from the coordinates of the third detection frames 1126 is constant in one direction (in the horizontal direction in this embodiment). The second detection frames 1124 are moved with their initial inclinations. The lower ends of the second detection frames 1124 contact a horizontal reference line 1014.

When the rotation position of a first wafer of the same lot is detected, the wafer or a jig wafer is placed on the stage 1005 in a chamber 1003 so that the notch portion of the wafer or the jig wafer enters the visual field of the photographing device 1007, the inclination of the wafer is nearly zero, and the center of the first detection frame 1122 nearly matches the center of the groove of the notch portion (see FIG. 37). The edge position detection section 1009Cg detects intersections 1124a and 1124b of the notch portion and the second detection frames 1124 that have been set by the second detection area frame setting section 1009Cb. As a result, distances a0 and b0 from the intersections 1124a and 1124b to the horizontal reference line 1014 are obtained. With the obtained distances a0 and b0, the wafer rotation amount calculation section 1009Ch calculates the initial wafer rotation amount θ0 according to the following formula.
θ0=(a0−b0)/1

Next, the wafer is placed on the stage 1005 to detect the rotation amount. The first detection area frame moving section 1009Cd detects and recognizes the notch portion of the wafer by for example the pattern matching method. At this point, the reference position 1112 of the first detection frame 1122 is moved according to the notch portion. FIG. 37 shows the first detection frame 1122 in the state that the first detection area frame moving section 1009Cd has recognized the notch portion of the wafer. At this point, although the second detection frames 1124 are moved as the first detection frame 1122 is moved, the second detection frames 1124 are moved with the inclinations that have been initially set (see FIG. 38). In addition, the third detection frames 1126 are moved as the first detection frame 1122 is moved. After the notch portion of the wafer has been recognized, the notch representative position detection section 1009Ce obtains the coordinates of the three intersections of the three detection frames 1126 and the notch portion. With the obtained coordinates of the three intersections, the notch representative position detection section 1009Ce obtains the coordinates of a center 1112′ of an arc 1110′ adjacent to the groove of the notch portion. The coordinates of the center 1112′ are designated as the coordinates of the notch representative position.

Next, the edge position detection section 1009Cg detects intersections 1124a and 1124b of the contour of the wafer and the second detection frames 1124. As a result, distances a and b from the intersections 1124a and 1124b to the horizontal reference line 1014 are obtained (see FIG. 38). With the obtained distances a and b and the initial wafer rotation amount θ, the wafer rotation amount calculation section 1009Ch obtains the current wafer rotation amount θ according to the following formula.
θ=(a−b)/L−θ0

Thus, only inclination of wafer misalignment information can be obtained.

(Modification)

According to the fourth embodiment, the number of second detection frames 1124 is two. Instead, with only one second detection frame 1124, the inclination of a wafer can be obtained. This structure will be described as a modification of the fourth embodiment. In the wafer rotation position detection apparatus according to this modification, only the left second detection frame 1124 of the two second detection frames 1124 shown in FIG. 37 is disposed.

According to this modification, the initial inclination θ0 of a wafer can be obtained according to the following formula.
θ0=Δx0/L
where Δx0 represents the distance between the reference position 1112 of the first detection frame 1122 and the left second detection frame 1124 (see FIG. 37). The real rotation amount θ of the wafer can be obtained according to the following formula.
θ=Δx/L−θ0

where Δx represents the distance between the reference position 1112 of the first detection frame 1122 and the left second detection frame 1124 (see FIG. 38).

Thus, this modification provides the same effect as the fourth embodiment of the present invention.

(Fifth Embodiment)

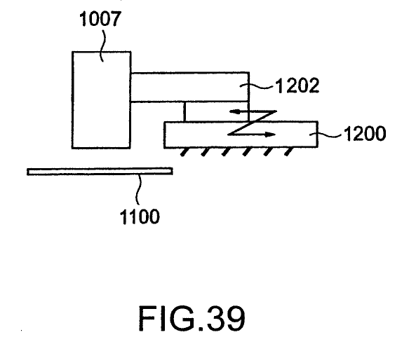

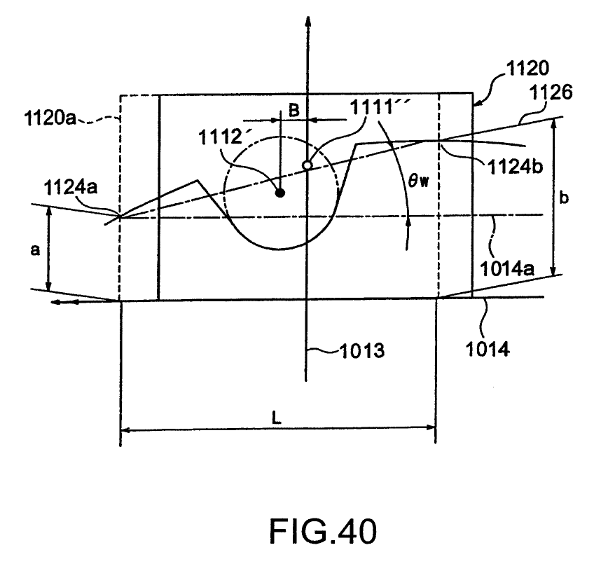

Next, with reference to FIG. 39 and FIG. 40, a wafer rotation position detection apparatus according to a fifth embodiment of the present invention will be described. According to the second to fourth embodiments, the inclination amount of a wafer is obtained by moving a visual field or a detection frame. In contrast, according to this embodiment, the inclination amount of a wafer is obtained by moving a photographing device 1007. Thus, as shown in FIG. 39, the photographing device 1007 is fixed to a sliding portion 1202 that slides on a fixed stage 1200 at least along a horizontal reference line. As the sliding portion 1202 is slid on the stage 1200, the photographing device 1007 is moved. Thus, the wafer rotation position detection apparatus also has a drive means (not shown) that drives the sliding portion 1202.

Firstly, as shown in FIG. 40, like the second embodiment, a reference notch representative position 1111″ is pre-set with a jig wafer or the like. At this point, the center of the visual field of the photographing device 1007 for example a CCD camera is aligned with the reference notch representative position 1111″ by center position alignment means (not shown). The aligned position is stored in storage means (not shown) and designated as the origin.

Next, a wafer 1100 is loaded into the apparatus so that a contour of the wafer 1100 including a notch enters the visual field of the CCD camera 1007. Like the first embodiment, a notch representative position detection section (not shown) obtains a notch representative position 1112 and obtains a deviation B of the obtained notch reference position and the reference notch representative position in the direction of a horizontal reference line 1014 (see FIG. 40). The drive means drives the sliding portion 1202 to move the CCD camera 1007 in the direction of the horizontal reference line for the deviation B. FIG. 40 shows a visual field 1120a of the photographing device 1007 that has been moved. Like the second to fourth embodiments, an edge position detection section (not shown) detects distances a and b from intersections 1124a and 1124b of the contour of the wafer 1100 and the left and right sides of the visual field 1120a of the CCD camera 1007 to the horizontal reference line 1014. As is clear from FIG. 40, an angle θw made of a straight line 1014a that passes through the intersection 1124a and that is in parallel with the horizontal reference line 1014 and a straight line 1126 that passes through the intersections 1124a and 1124b is a wafer rotation amount for which the inclination of the wafer 1100 is removed (leveled). With the detected distances a and b and a width L of the visual field of the CCD camera 1007 in the direction of the horizontal reference line 1014, a wafer rotation amount calculation section (not shown) obtains a rotation amount θw of the wafer 1100. The rotation amount θw can be obtained according to the following formula.
θw=(a−b)/L

As described above, according to this embodiment, the rotation position of a wafer can be detected with one camera.

(Sixth Embodiment)

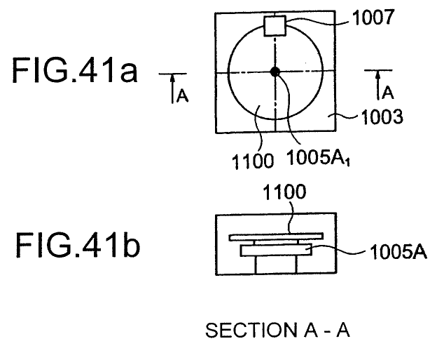

Next, with reference to FIG. 41, a wafer rotation position detection apparatus according to a sixth embodiment of the present invention will be described. The wafer rotation position detection apparatus according to this embodiment has a structure of which the stage 1005 of the second to fifth embodiment, on which the wafer 1100 is placed, is replaced with a θ axis stage 1005A that can be rotated around a rotation axis 1005A₁. This structure allows the rotation position of a wafer 1000 to be corrected in a chamber 1003 and the inclination of the wafer 1100 to be removed (leveled).

Of course, according to this embodiment, the rotation position of a wafer can be detected with one camera.

(Seventh Embodiment)

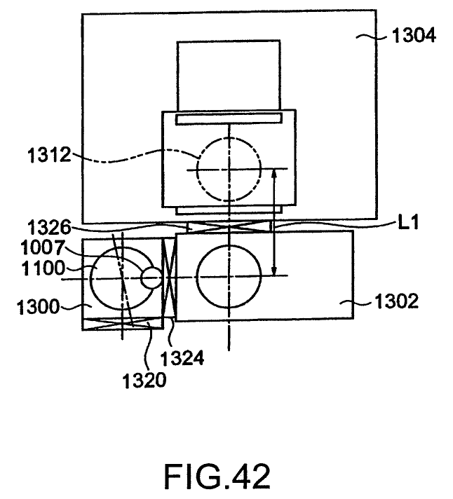

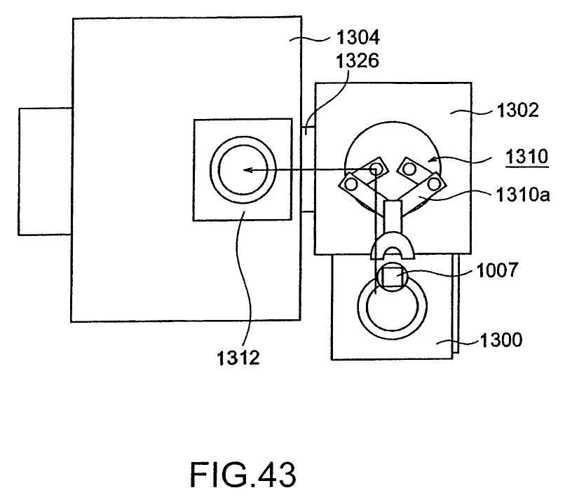

Next, with reference to FIG. 42 to FIG. 46, a single wafer treatment apparatus according to a seventh embodiment of the present invention will be described. The single wafer treatment apparatus according to this embodiment has a load lock chamber 1300 that allows a wafer under a normal atmosphere to be conveyed to a vacuum atmosphere through a gate valve 1320, a transfer chamber 1302 connected to the load lock chamber 1300 through a gate value 1324, and a wafer treatment chamber 1304 connected to the transfer chamber 1302 through a gate valve 1326. The load lock chamber 1300 has a wafer rotation position detection apparatus according to one of the second to fifth embodiments. In FIG. 42, reference numeral 1007 represents a photographing device composed of a CCD camera that photographs an area including a notch portion of a wafer 1100. The transfer chamber 1302 has a vacuum atmospheric robot 1310 (see FIG. 43) that removes the wafer 1100 from the load lock chamber 1300 and conveys the wafer 1100 to the wafer treatment chamber 1304. In addition, the wafer treatment chamber 1304 has a treatment device that treats the wafer 1100 under a vacuum atmosphere. The treatment device is for example an electron beam exposure device (not shown) that emits an electron beam onto resist formed on a wafer. The electron beam exposure device has an XY stage 1312 on which the wafer 1100 is placed. The load lock chamber 1300, the transfer chamber 1302, and the wafer treatment chamber 1304 are structured so that vacuum degrees increase in the order.

Next, the operation of the apparatus according to this embodiment will be described.

Firstly, the wafer 1100 is loaded into the load lock chamber 1300. The wafer rotation position detection apparatus that has the CCD camera 1007 detects a θ deviation (rotation amount θw in the second embodiment) against reference coordinates. Thereafter, the θ deviation data are supplied to a control section (not shown) of the vacuum atmospheric robot 1310 and a stage drive section (not shown) of the XY stage 1312. As a result, the control section of the vacuum atmospheric robot 1310 calculates a rotation axis moving command value according to the θ deviation data to convey the wafer 1100 from the load lock chamber to the wafer treatment chamber 1304. In addition, the stage drive section of the XY stage 1312 calculates a moving amount (=L1×θ deviation) of the X axis loading position of the XY stage 1312 according to the θ deviation data, where L1 represents the distance between the center of the rotation axis of the vacuum atmospheric robot 1310 and the center of the wafer conveyance device on the XY stage 1312 (see FIG. 42).

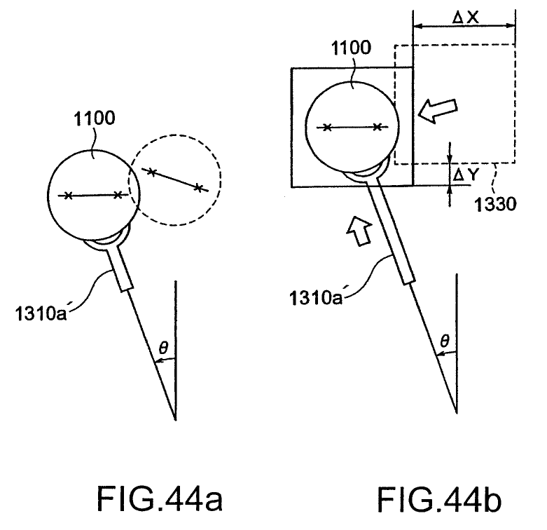

Next, as shown in FIG. 44A, the vacuum atmospheric robot 1310 removes the wafer 1100 from the load lock chamber 1300. At this point, a hand insertion position at an end of an arm 1310a of the vacuum atmospheric robot 1310 is a teaching position (reference position). Thereafter, the arm 1310a is rotated to the wafer treatment chamber 1304. At this point, the rotation angle corresponds to the foregoing rotation axis moving command value. The rotation axis moving command value is a value of which the reference rotation angle from the teaching position of the load lock chamber 1300 to the teaching position of the wafer treatment chamber 1304 and the θ deviation are added (see FIG. 44A).

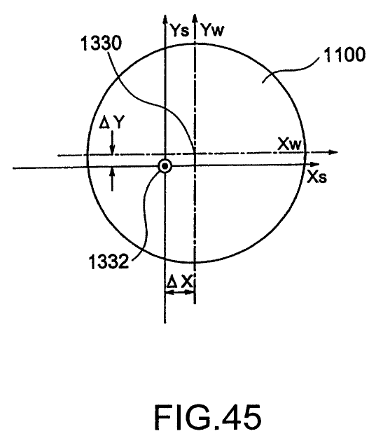

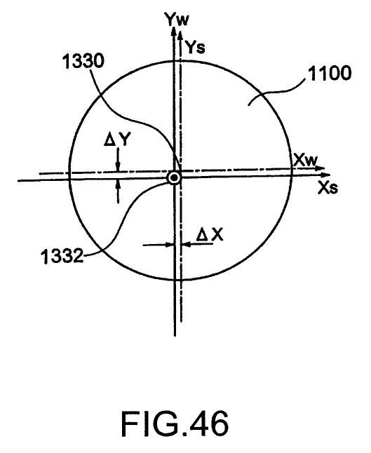

After the arm 1310a has been rotated, the vacuum atmospheric robot 1310 extends a horizontally extending/shrinking axis 1310a′ and moves it on a predetermined horizontal plane. The wafer 1100 at the end of the horizontally extending/shrinking axis 1310a′ deviates from a reference transfer position 1330 (see FIG. 44B) on the XY stage 1312 by ΔX and ΔY according to the moved amount of the rotation axis. The deviated amounts ΔX and ΔY are aligned by moving the XY stage 1312 so that the center of the reference wafer on the XY stage 1312 is aligned with the center of the conveyed wafer within an allowable value. When the relationships of the coordinate axes Xw and Yw of the wafer 1100 conveyed onto the wafer treatment chamber 1304 and the coordinate axes Xs and Ys of the XY stage 1312 are as shown in FIG. 45, the XY stage 1312 is moved so that the deviation amounts ΔX and ΔY between the center 1332 of the reference wafer on the XY stage 1312 and the center 1330 of the conveyed wafer are within the predetermined allowable values (see FIG. 46).

In this manner, the center 1332 of the reference wafer on the XY stage 1312 is aligned with the center 1330 of the conveyed wafer within the allowable values. Thereafter, the wafer 1100 is placed on the XY stage 1312.

According to this embodiment, the wafer rotation position detection apparatus for the wafer 1100 is disposed in the load lock chamber 1300. Instead, the wafer rotation position detection apparatus may be disposed in the transfer chamber 1302 or the wafer treatment chamber 1304. In other words, as long as the wafer rotation position detection apparatus can detect the rotation position of the wafer 1100 before it is placed on the XY stage 1312, the structure of the wafer rotation position detection apparatus is not limited to the foregoing example.

After the air atmosphere conveyance system has preformed the alignment process, the rotation amount θw of the wafer 1100 conveyed to the vacuum environment load lock chamber 1300 is as small as around 0.5 degrees. The allowable value of the rotation amount θw of the XY stage 1312 is for example equal to or smaller than 0.05 degrees. Thus, the deviation amounts ΔX and ΔY between the center 1330 of the wafer aligned by the rotation operation of the vacuum atmospheric robot and the center 1332 of the reference wafer on the XY stage are large on the side of the stage moving axis that is in parallel with the tangent of the arm 1310a of the vacuum atmospheric robot and that are small on the side of the axis perpendicular to the stage moving axis. Thus, by moving the stage on the side of the stage moving axis in parallel with the tangent of the arm 1310a of the vacuum atmospheric robot, the centers can be sufficiently aligned (see FIGS. 45 and 46).

As described above, according to this embodiment, without need to newly dispose a dedicated wafer rotation alignment mechanism, the wafer rotation position can be aligned by using an existing mechanism or modifying another mechanism. The angular misalignment θw of the angles of the coordinates Xs and Ys of the moving axis of the XY stage disposed in the wafer treatment chamber and the coordinates Xw and Yw of the pattern on the wafer conveyed onto the XY stage can be kept within an allowable value. In other words, by using the wafer conveyance robot, the XY stage of the wafer treatment chamber, and the function of the rotation axis of the robot, the rotation position of the wafer can be aligned. Thus, misalignment amounts ΔX and ΔY that take place as a result of a change of the moving amount of the rotation axis of the robot can be kept within allowable values by using the XY stage.

Thus, the conventional dedicated wafer rotation alignment mechanism can be omitted. As a result, the misalignment amounts of the coordinates Xs and Ys of the moving axis of the XY stage and the coordinates Xw and Yw of the pattern forming axis can be corrected within allowable values without need to the installation and maintenance costs for the foregoing dedicated mechanism and countermeasures against gas, dust, and metallic contamination due to the dedicated mechanism.

Since the θ axis stage can be omitted from the XY stage, a factor for occurrence of a relative misalignment between a position detection mirror disposed on the XY stage and a wafer can be removed. Thus, the lithography positional accuracy of an electron beam emitted onto a wafer can be improved. In other words, the apparatus according to this embodiment contributes to the improvement of the lithography performance and the fabrication cost competition.

(Eighth Embodiment)

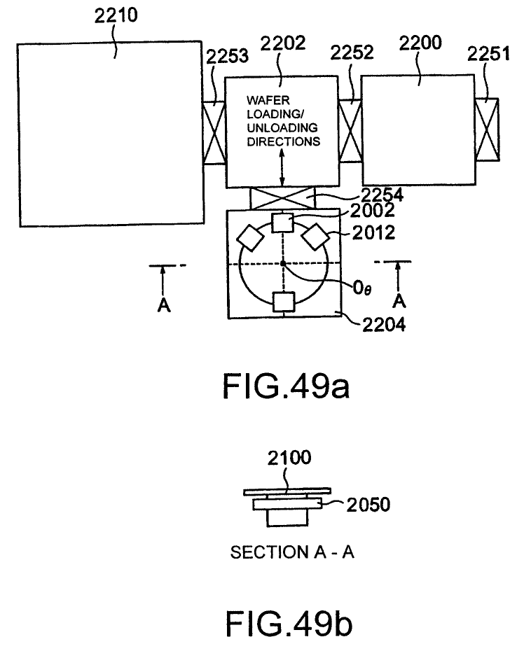

FIG. 49A and FIG. 49B show an example of a vacuum atmospheric wafer conveyance system of a single wafer treatment apparatus that has a wafer alignment apparatus according to an eighth embodiment of the present invention. FIG. 49A is a plan view showing a layout of devices of a wafer conveyance system. FIG. 49B is a sectional view showing the wafer conveyance system taken along line A-A shown in FIG. 49A. A load lock chamber 2200 has a gate valve 2251 and a gate valve 2252 that are disposed adjacent to a normal atmospheric device and a vacuum atmospheric robot chamber 2202, respectively, so that a semiconductor wafer W can be loaded and unloaded under an air atmosphere and under a vacuum atmosphere. The vacuum atmospheric robot chamber 2202 has a vacuum atmospheric robot (not shown). The vacuum atmospheric robot conveys a wafer to a treatment chamber 2210 and a wafer angle correction chamber 2204 connected to the vacuum atmospheric robot chamber 2202 through gate valves 2253 and 2254, respectively.

In the treatment chamber 2210, a wafer is treated. For example, a pattern is transferred or lithographed on a resist film on a wafer using for example an electron beam. An exposure device that performs the exposure treatment has an XY stage that two-dimensionally moves the wafer surface against an emission point of an electron beam emission column. The XY stage has a function for rotating the wafer around a θ axis perpendicular to the XY stage. The XY stage may have a function for adjusting the rotation amount of the θ axis. However, when the XY stage has these functions, since the structure of the stage in the treatment chamber 2210 becomes complicated and large, the XY table according to this embodiment does not have the function for rotating the wafer around the θ axis. Thus, as shown in FIG. 49A, a vacuum atmospheric chamber (wafer angle correction chamber) 2204 is newly disposed adjacent to the vacuum atmospheric robot chamber 2202 through the gate valve 2254 in front of the treatment chamber 2210. The wafer angle correction chamber 2204 has the function for aligning the rotation position for a wafer 2100. According to this embodiment, the wafer angle correction chamber 2204 has a stage 2050 that has only a function for aligning the rotation position of the wafer 2100 (hereinafter this stage is referred to as the θ axis stage 2050). The θ axis stage 2050 accomplishes the rotation alignment of a wafer by the following structure and method.

The θ axis stage 2050 has a drive mechanism. The drive mechanism can align a wafer with a high accuracy. The θ axis stage 2050 aligns a wafer with high accuracy and high alignment reproducibility using a ultrasonic motor and a ball screw.

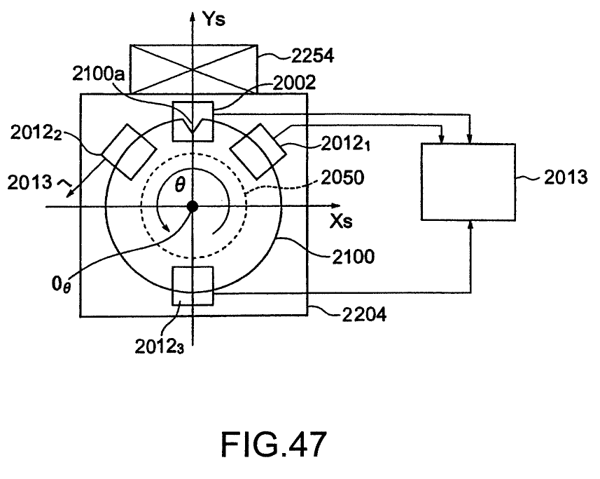

FIG. 47 shows the structure of the wafer alignment apparatus according to this embodiment. The wafer alignment apparatus according to this embodiment is disposed in the wafer angle correction chamber 2204. The wafer alignment apparatus has the stage on which only the rotation position of the wafer 2100 can be adjusted, a position detector 2002 that detects a reference point of a notch groove 2100a of the wafer 2100, three wafer position detectors 2012₁, 2012₂, and 2012₃ that detect edge positions of the wafer 2100 and obtain the center thereof, and an image process device 2013. According to this embodiment, although the position detectors 2002, 2012₁, 2012₂, and 2012₃ each have a CCD camera, they may have an optical microscope instead of the CCD camera. The wafer alignment apparatus has an orthogonal three-dimensional coordinate system whose origin is the center O_{θ} of the rotation of the θ axis stage 2050. The two-dimensional coordinates of the horizontal plane are denoted by (Xs, Ys) and the rotation axis perpendicular to the horizontal plane is defined as the θ axis.

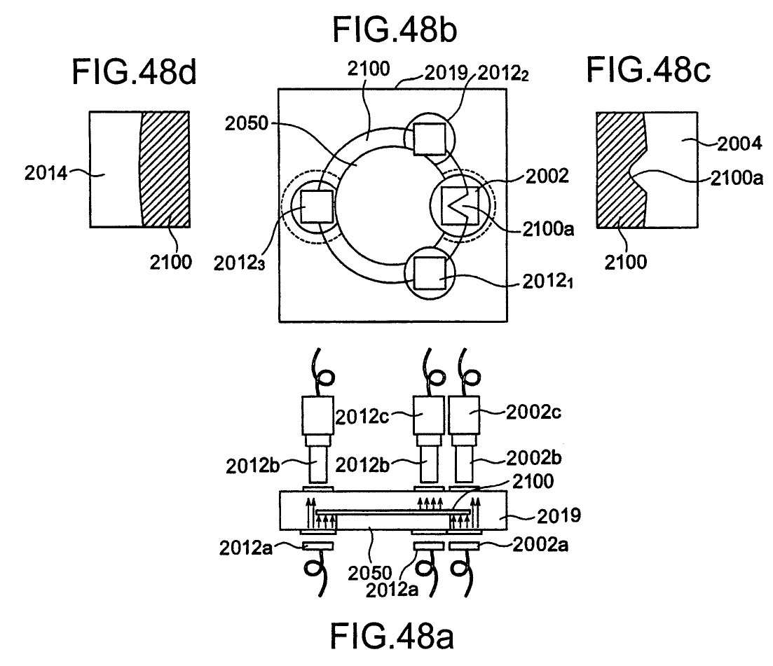

FIG. 48A to FIG. 48D show an example of the specific structure of the position detectors 2002, 2012₁, 2012₂, and 2012₃. FIG. 48A is a side view showing the structure of each position detector. FIG. 48B is a plan view showing a layout of the position detectors. FIG. 48C is a schematic diagram showing a visual field observed by the position detector 2002. FIG. 48D is a schematic diagram showing a visual field observed by the position detector 2012₁.

At least part of the θ axis stage 2050 on which the wafer 2100 is placed is disposed in an alignment chamber 2019 composed of a transparent housing. The position detector 2002 has an LED 2002a that emits light and a CCD camera 2002c that detects light emitted from the LED 2002a through an tele-centric lens 2002b. Likewise, each of the position detectors 2012₁, 2012₂, and 2012₃ has an LED 2012a that emits light and a CCD camera 2012c that detects light emitted from the LED 2012a through a tele-centric lens 2012b. Thus, when the position detector 2002 observes the outer vicinity of the notch groove 2100a of the wafer 2100, the position detector 2002 obtains an observation visual field 2004 shown in FIG. 48C. When the position detector 2012₃ observes the outer vicinity of the wafer 2100, the position detector 2012₃ obtains an observation visual field 2014 shown in FIG. 48D.

Images obtained by the position detectors 2002, 2012₁, 2012₂, and 2012₃ are processed by the image process device 2013. The image process device 2013 obtains the center and the notch reference point of the wafer 2100. A position detector that detects the center point of the wafer 2100 may be a position detector that has one camera that can detect the whole wafer. Instead, one of the three position detectors 2012₁, 2012₂, and 2012₃, which detect the center point of the wafer 2100, may be used in common with a detector that detects the notch reference point of the wafer 2100. In the following description, it is assumed that the four position detectors 2002, 2012₁, 2012₂, and 2012₃ are used and they are placed at predetermined positions of the orthogonal three-dimensional coordinate system on the θ axis stage 2050.

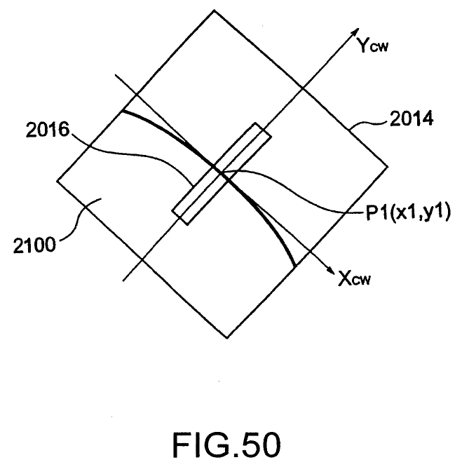

FIG. 50 is a schematic diagram showing the visual field 2014 observed by one of the three position detectors 2012₁, 2012₂, and 2012₃ shown in FIG. 47. Any point P1 (x1, y1) of the edge of the wafer 2100 is decided by setting a detection area 2016 in the CCD camera of the position detector.

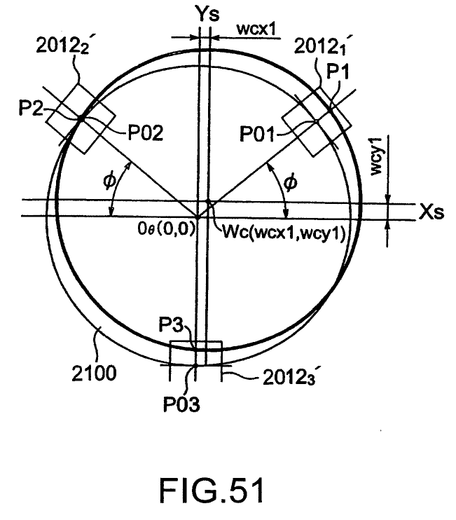

Next, with reference to FIG. 51, a method of obtaining the center of the wafer 2100 with three points P1, P2, and P3 of the edge of the wafer 2100 detected by the three position detectors 2012₁, 2012₂, and 2012₃ will be described. It is assumed that the outer shape of the wafer 2100 is circular except for a notch groove.

The visual fields of the CCD cameras of the position detectors 2012₁, 2012₂, and 2012₃ have two-dimensional coordinates (Xcw1, Ycw1), (Xcw2, Ycw2), and (Xcw3, Ycw3), respectively. Each of the CCD cameras has been set at a predetermined position of two-dimensional coordinates (Xs, Ys) on the horizontal plane of the θ axis stage 2050. Thus, the relative positions of the CCD cameras to the two-dimensional coordinates (Xcw1 Ycw1), (Xcw2, Ycw2), and (Xcw3, Ycw3) are known. For example, as shown in FIG. 51, the CCD cameras 2012₁′ and 2012₂′ are inclined in the plus direction and the minus direction to the Xs axis of the θ axis stage 2050 by φ, respectively. These directions match Ycw1 and Ycw2 axes of the CCD cameras 2012₁′ and 2012₂′. In addition, the CCD camera 2012₃′ is inclined in the minus direction of an Ys axis of the θ axis stage 2050. The Ycw3 axis matches the Ys axis of the θ axis stage 2050. In addition, reference points P01, P02, and P03 are set in the observation visual fields of the CCD cameras 2012₁′, 2012₂′, and 2012₃′. The coordinate values of the coordinate systems of the CCD cameras and the coordinate values of the coordinate system of the θ axis stage at the reference points P01, P02, and P03 are known.

With the coordinate values of the coordinate systems of the CCD cameras and the coordinate values of the coordinate system on the θ axis stage at the reference points P01, P02, and P03 and the coordinate values of the coordinate systems of the CCD cameras at the detected three points P1, P2, and P3 on the edge of the wafer 2100, the image process device 2013 calculates coordinate values P1 (x1, y1), P2 (x2, y2), and P3 (x3, y3) of the coordinate systems on the θ axis stage at the detected three points P1, P2, and P3 on the edge of the wafer 2100. With these coordinate values, the image process device 2013 obtains the center point Wc of the wafer 2100 as the center of a circle that passes through the three points P1, P2, and P3. The image process device 2013 calculates coordinate values (wcx1, wcyl) of the center point Wc of the coordinate system on the θ axis stage according to the following formula.
wcx1={(x1²+y1²−x3²−y3²)(y2−y3)(x2²+y2²−x3²−y3²)(y1−y3)}/{2(x1−x3)(y2−y3)−2(x2−x3)(y1−y3)}
wcy1={(x1²+y1²−x3²−y3²)(x2−x3)−(x2²+y2²−x3²−y3²)(x1−x3)}/{2(y1−y3)(x2−x3)−2(y2−y3)(x1−x3)}

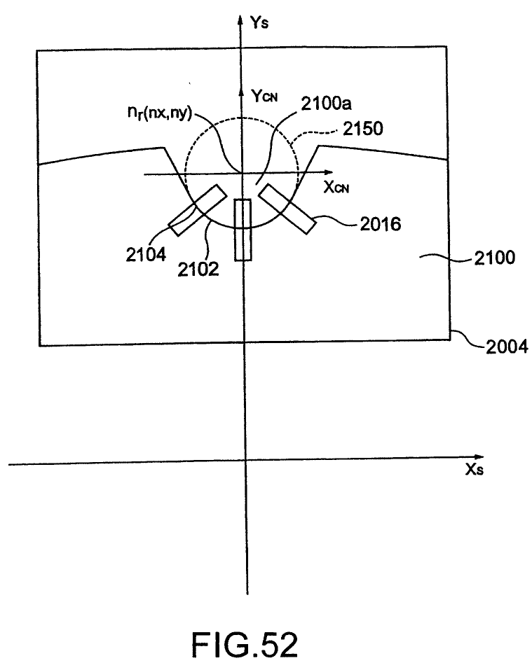

Next, with reference to FIG. 52, a method of obtaining a reference point of a notch groove with an image captured by the CCD camera of the position detector 2002 will be described. FIG. 52 is a schematic diagram describing a method of obtaining a notch reference point nr with an arc 2102 at the bottom of a notch groove 2100a of the wafer 2100. A two-dimensional coordinate system (X_{CN}, Y_{CN}) is set in the visual field 2004 of the CCD camera of the position detector 2002, which detects the notch reference point nr. The notch reference point nr is detected by setting any three points on the arc 2102 at the bottom of the notch groove 2100a as a detection area 2016 of the CCD camera. The notch reference point nr is obtained as the center of a virtual circle 2150 that passes through these three points. The image process device 2013 calculates the coordinate values of the coordinate system in the visual field of the CCD camera at the center of the virtual circle with the coordinate values of the three points.

Thus, the notch reference point is obtained by the following procedure. Before a wafer is loaded into the vacuum atmospheric chamber 2204, which has the wafer alignment device, the wafer is rotated by a known “aligner” so that the notch groove enters the observation visual field 2004 of the camera. Thereafter, the wafer is loaded into the vacuum atmospheric chamber 2204. The image process device 2013 obtains coordinates of any three points on the arc 2102 with an image of the arc 2102 at the bottom of the notch groove 2100a recognized by the CCD camera, which detects the reference point of the notch groove and calculates the coordinate values of the center point nr of the virtual circle 2150 that passes through the three points with the coordinate values of the three points. This center point becomes the notch reference point.

Detailed information of tolerance of the notch groove 2100a is defined in the SEMI standard. Although the shape of the notch groove 2100a varies in each manufacturer, if the detection area is set so that the shape of the arc 2102 at the bottom of the notch groove 2100a can vary within the tolerance, the notch reference point can be accurately detected.

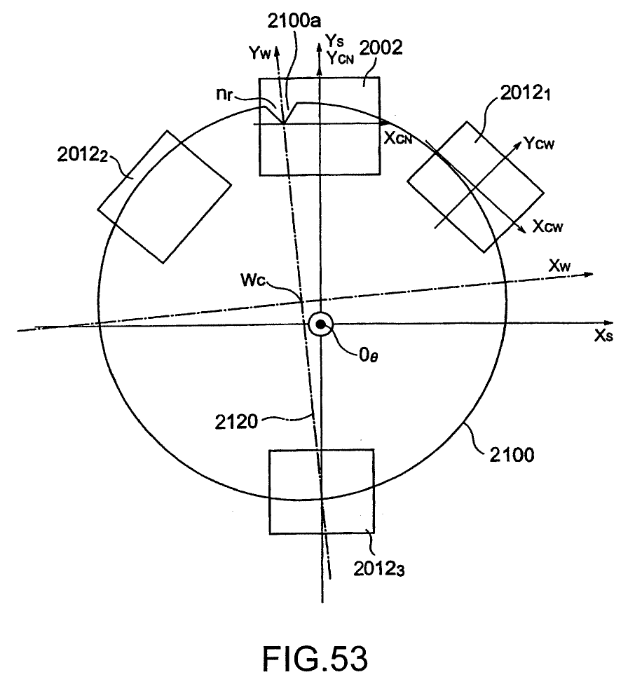

FIG. 53 shows the relationship of the position of the wafer 2100 on the alignment device for a wafer, the θ axis stage, and the wafer position detector. A coordinate system (Xs, Ys) having center O has been set to the θ axis stage 2050. Two-dimensional coordinates (Xw, Yw) on the horizontal plane of the wafer 2100 placed on the θ axis stage 2050 are denoted by (Xw, Yw). The Yw axis is a straight line that passes through the center Wc of the wafer 2100 and the notch groove 2100a and that is in parallel with the crystalline direction of the wafer 2100. This straight line is defined as the reference axis of the wafer 2100. On the other hand, the Xw axis is an axis perpendicular to the Yw axis.

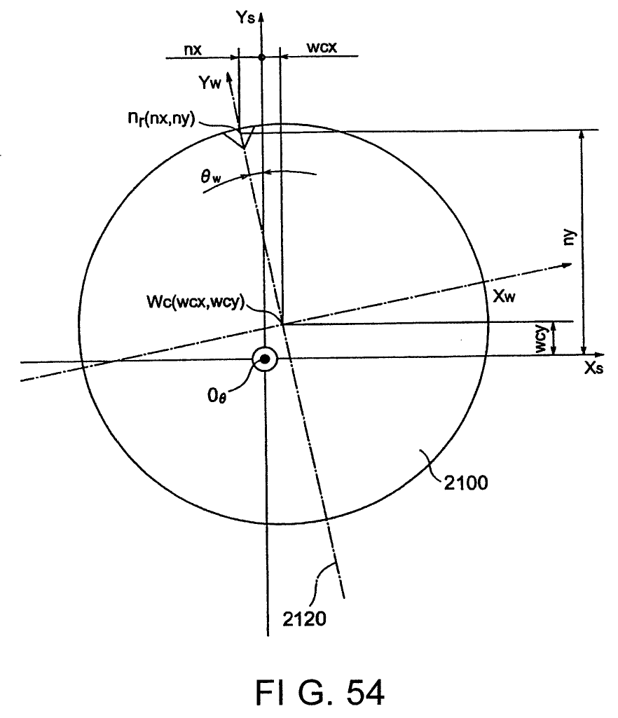

Next, with reference to FIG. 54, a method of obtaining an inclination angle θw of the wafer reference axis Yw against the coordinate system of the θ axis stage with the center point nr and the reference point of the notch groove of the wafer 2100. According to this embodiment, a straight line that passes through the wafer center point Wc obtained by the foregoing position detectors 2012₁, 2012₂, and 2012₃ and the notch reference point nr obtained by the position detector 2002 are defined as a wafer reference axis.

When the angle made of the Ys axis of the two-dimensional coordinate system of the horizontal plane on the θ axis stage 2050 having the rotation center Oθ as the origin and the reference axis of the wafer is denoted by θw; the coordinates of the center point Wc of the wafer 2100 are denoted by (wcx, wcy); and the coordinates of the notch reference point nr are denoted by (nr, ny), then the rotation angle θw of the wafer 2100 can be obtained according to the following formula.
θw=tan⁻¹{(Wcx−nx)/(ny−wcy)}

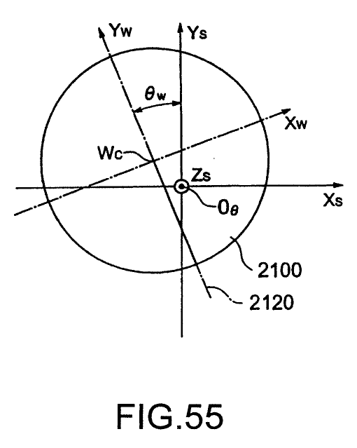

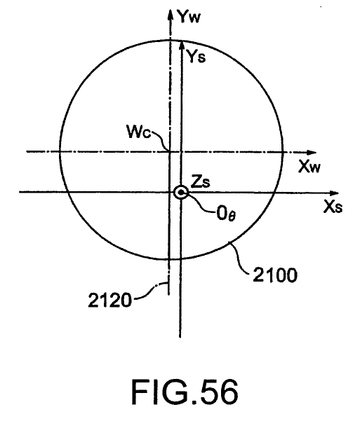

Next, with reference to FIG. 55 and FIG. 56, a method of obtaining the moving direction and the moving amount of the θ axis stage with the obtained wafer rotation angle θw will be described. FIG. 55 shows the case that the reference axis 2120 of the conveyed wafer 2100 is aligned with the Ys axis to be corrected. When the rotation angle θw of the wafer 2100 is a drive amount of the θ axis stage and the θ axis stage is driven in the clockwise direction, the wafer reference axis 2120 becomes in parallel with the Ys axis (see FIG. 56). In this state, the rotation alignment for the wafer has been accomplished.

According to this embodiment, since the vacuum atmospheric chamber 2204 that corrects the rotation angle for a wafer does not have a stage on which the X and Y directions of the wafer are corrected, information of coordinate values wcx and wcy is supplied to the XY stage of the treatment chamber 2210. When a wafer is conveyed onto the XY stage, it is moved for the coordinate values wcx and wcy. As a result, the X and Y positions for the wafer can be corrected.

According to this embodiment, since the coordinate values (wcx, wcy) of the wafer 2100 having the center Wc on the θ axis stage have been obtained, when the θ axis stage 2050 has a function for horizontally moving the wafer 2100, not only the rotation angle θw, but the position on the Xs axis and the Ys axis can be corrected.

Instead, when the θ axis stage is driven and the reference axis 2120 of the wafer 2100 matches a coordinate component that is perpendicular to the coordinate axis Ys in the wafer loading/unloading direction that passes through the rotation center O_{θ} of the θ axis stage 2050, the rotation alignment function can be accomplished.

According to this embodiment, the center point and the reference axis of a wafer can be detected without influence of the dimensional tolerance of the wafer and a film formed on the wafer. Thus, the accuracy of the rotation alignment for a wafer that is performed with the center point and the reference axis can be improved. In addition, when the arc shape of the notch groove is within the dimensional tolerance defined in the SEMI standard, the single wafer treatment can be successively performed for wafers without need to change constants and so forth used for internal calculations. As a result, the treatment time can be prevented from becoming long.

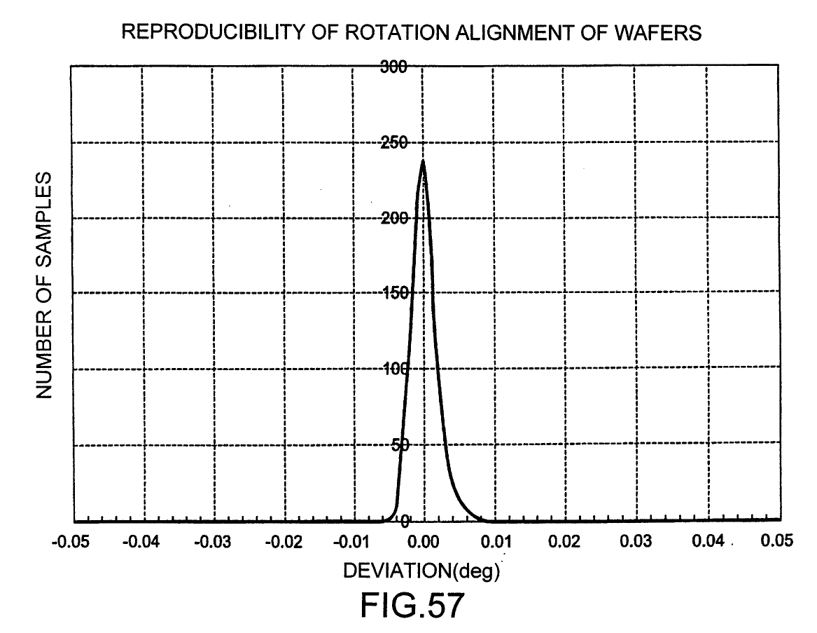

FIG. 57 shows results of rotation alignment for various wafer using the alignment apparatus according to this embodiment. As is clear from FIG. 57, accuracy of rotation alignment for wafers is as high as around 0.01 deg (0.17 mrad). In addition, it is clear that the deviation of rotation alignment for wafers is very small.

In addition, the wafer alignment apparatus does not need to have an XY stage. The rotation alignment can be accomplished by only a θ axis stage. Thus, the structure and control axes for the rotation alignment can be simplified. In addition, the structure and control axes of the XY stage of the treatment chamber can be simplified. Thus, the reliability of the apparatus can be improved. Since the number of control axes can be decreased, the rotation alignment can be performed at relatively high speed.

Since the wafer alignment apparatus according to this embodiment is of non-contact type, a wafer does not contact with a wafer support surface. Thus, a problem of wear-out does not occur. Thus, the wafer is not contaminated with particles. In addition, a flaw does not take place on the front surface of the wafer. Moreover, a complicated structure such as a penetration amount check function for push pins is not required.

Although the present invention has been shown and described with respect to best mode embodiments thereof, it should be understood by those skilled in the art that the foregoing and various other changes, omissions, and additions in the form and detail thereof may be made therein without departing from the spirit and scope of the present invention.

1. A substrate treatment apparatus treating a substrate under treatment, comprising:
a plurality of gas flow mechanisms disposed at least one side of the substrate treatment apparatus that is structured from a plurality of space portions each of which is linearly shaped and a gas flow in each of the space portions is formed in a vertical direction;
a gas supply mechanism that supplies a gas of which temperature or/and humidity is set to at least one of the plurality of gas flow mechanisms; and
a collection mechanism that collects the gas from at least one of the plurality of gas flow mechanisms.

2. A substrate treatment apparatus treating a substrate under treatment, comprising:
a plurality of gas flow mechanisms disposed at least one side of the substrate treatment apparatus that is structured from a space portion which is linearly shaped and a gas flow in a vertical direction is formed therein;
a gas supply mechanism that supplies a gas of at least temperature or/and humidity is set to at least one of the plurality of gas flow mechanisms;
a collection mechanism that collects the gas from at least one of the plurality of gas flow mechanisms;
a heat body disposed inside of at least one of the gas flow mechanisms; and
a control mechanism that controls the heat body.

3. The substrate treatment apparatus as set forth in claim 1,
wherein a direction of flow of the gas of the gas flow mechanism that is supplied with the gas from the gas supply mechanism is opposite to a direction of flow of the gas of the gas flow mechanism that is collected by the collection mechanism.

4. The substrate treatment apparatus as set forth in claim 1,
wherein a direction of flow of the gas of the gas flow mechanism that is supplied from the gas supply mechanism is formed downward and a direction of flow of the gas of the gas flow mechanism that is collected by the collection mechanism is formed upward.

5. The substrate treatment apparatus as set forth in claim 1,
wherein a first gas supply opening of each of the gas flow mechanisms that is supplied with gas from the gas supply mechanism and a second gas supply opening of each of the gas flow mechanisms from where the gas is collected by the collection mechanism is disposed at an upper portion of each of the plurality of the gas supply mechanisms.

6. The substrate treatment apparatus as set forth in claim 1,
wherein a first gas supply opening of each of the gas flow mechanisms that is supplied with gas from the gas supply mechanism and a second gas supply opening of each of the gas flow mechanisms from where the gas is collected by the collection mechanism are disposed at an upper portion of each of the plurality of the gas supply mechanisms and the lower position of each of the gas flow mechanisms is structured such that the gas is freely supplied from the gas flow mechanism that is supplied with gas from the gas supply mechanism to the gas flow mechanism from which the gas is collected by the gas collection mechanism.

7. The substrate treatment apparatus as set forth in claim 1, further comprising:
a gas supply path disposed at an upper portion of the plurality of the gas flow mechanism that supplies gas to an upper portion of the plurality of gas flow mechanisms which is supplied with gas from the gas supply mechanism; and
a gas collection path, disposed at an upper portion of the plurality of the gas flow mechanism that collects the gas from a gas collection opening of the plurality of gas flow mechanisms which the gas collection mechanism collects the gas from.

8. The substrate treatment apparatus as set forth in claim 1,
wherein a supply path that supplies a gas at least temperature and humidity thereof is controlled to an unit portion that is structured to be freely connectable with another substrate treating apparatus for treating the substrate using a resist solution or/and a developing solution is provided at an upper portion of the plurality of gas flow mechanisms.

9. The substrate treatment apparatus as set forth in claim 1,
wherein the temperature of the gas is set at approximately the same as, or lower than, the atmospheric temperature of another substrate treating apparatus for performing an exposure treatment to the substrate under treatment using a resist solution or/and a developing solution.

10. The substrate treatment apparatus as set forth in claim 1,
wherein a magnetic shield is disposed at a position inner than the position where the gas flow mechanism is disposed.

11. A substrate treatment method treating a substrate in a treatment chamber, comprising the steps of:
supplying the gas at least temperature or/and humidity thereof is set so that the gas flows toward a vertical direction against at least a pair of sides facing each other surrounding the exposure treatment device; and
collecting the gas by forming a flow of the gas at least temperature or/and the humidity thereof is set in an opposite direction to the vertical direction.

12. The substrate treatment method as set forth in claim 11,
wherein the temperature of the gas is set at approximately the same as, or lower than, the atmospheric temperature of the other substrate treatment apparatus for performing an exposure treatment for the substrate under treatment using a resist solution or/and a developing solution.

13. The substrate treatment method as set forth in claim 11,
wherein a first gas supply opening of the gas flow mechanism that is supplied with gas from the gas supply mechanism and a second gas supply opening of the gas flow mechanism from where the gas is collected by the collection mechanism are disposed at an upper portion of each of the plurality of the gas supply mechanisms.

14. The substrate treatment method as set forth in claim 11,
wherein the gas in the supply step where the gas is being supplied in a vertical direction is supplied such that to form a flow of the gas at least temperature or/and the humidity thereof is set from an upper portion towards the lower portion and the gas is collected in the collection step where the gas is being collected as forming a flow of the gas at least temperature or/and humidity thereof is set in a direction opposite to the vertical direction from the lower portion to the upper portion.

15. The substrate treatment method as set forth in claim 11, further comprising the steps of:
supplying a gas at least temperature and humidity thereof is controlled to an unit portion disposed at an upper portion of the treatment chamber that is structured to be connectable with another substrate treating apparatus that treats the substrate under treatment by supplying a resist solution or/and a developing solution.

16. The substrate treatment method as set forth in claim 15,
wherein the temperature of the gas is set at approximately the same as, or lower than, the atmospheric temperature of another substrate treating apparatus for performing an exposure treatment for the substrate under treatment using the resist solution or/and the developing solution.
